(19) United States
(12) Patent Application Publication
(10) Pub. No.: US 2026/0063932 A1
(43) Pub. Date: Mar. 5, 2026

(54) ELECTRO-ABSORPTION MODULATOR AND OPTICAL SEMICONDUCTOR DEVICE

(71) Applicant: NeoPhotonics Corporation, San Jose, CA (US)

(72) Inventor: Keigo TACHIBANA, Tokyo (JP)

(21) Appl. No.: 19/042,552

(22) Filed: Jan. 31, 2025

(30) Foreign Application Priority Data
Aug. 28, 2024 (JP) 2024146839
Nov. 1, 2024 (JP) 2024192902

(51) Int. Cl. G02F 1/015; G02F 1/017; H01S 5/023; H01S 5/026; H01S 5/042

(52) U.S. Cl. CPC G02F 1/0157; G02F 1/01708; H01S 5/023; H01S 5/0265; H01S 5/0425

(57) ABSTRACT

Provided are an electro-absorption modulator and an optical semiconductor device which are excellent in high extinction ratio characteristics and high-speed operation. The electro-absorption modulator includes: a semi-insulating semiconductor layer; a first electro-absorption modulator section including a first n-type semiconductor layer, a first absorption layer, and a first p-type semiconductor layer; a second electro-absorption modulator section including a second p-type semiconductor layer, a second absorption layer, and a second n-type semiconductor layer; a connection waveguide layer arranged between the first absorption layer and the second absorption layer; a first EA electrode electrically connected to the first p-type semiconductor layer and electrically connected to an outside; a second EA electrode electrically connected to the second n-type semiconductor layer and electrically connected to the outside; and a connection medium configured to electrically connect the first n-type semiconductor layer and the second p-type semiconductor layer to each other.

### CROSS-REFERENCE TO RELATED APPLICATION

This Patent Application claims priority to Japan Patent Application No. JP2024-192902, filed on Nov. 1, 2024, and Japan Patent Application No. JP2024-146839, filed on Aug. 28, 2024. The disclosure of the prior Applications is considered part of and is incorporated by reference into this Patent Application.

### TECHNICAL FIELD

The present disclosure relates generally to an electro-absorption modulator and to an optical semiconductor device.

### BACKGROUND

As a light source for optical communication can be obtained by combining a laser for oscillating continuous light and an external modulator for converting the laser light into an optical modulated signal. An electro-absorption (EA) modulator is a type of external modulator. Further, in some cases, the electro-absorption modulator is mounted on a wiring substrate (a submount or the like) on which transmission lines are formed, and an obtained device is used as an optical semiconductor device.

### SUMMARY

EA modulators have small sizes and are excellent in extinction ratio characteristics and frequency response characteristics. However, along with an increase in optical communication capacity, there is a demand for the EA modulators to adapt to higher-speed operation. In order to adapt to high-speed operation, it is effective to reduce a parasitic capacitance of the EA modulator. In order to reduce the parasitic capacitance, it is effective to reduce an EA modulator length. However, when the EA modulator length is reduced, the extinction ratio characteristics are degraded. In some cases, this problem is solved by electrically connecting two EA modulators in series to each other.

In some cases, two EA modulators are individually prepared, and a power supply circuit is used for connection between the two EA modulators. An electrode on a back side of at least one of the EA modulators and an electrode on a front side of the other EA modulator can be connected to each other, and a wire or a transmission line is arranged. This wire or transmission line has an inductance component or a capacitance component itself, and hence has a disadvantage in high-speed operation. In some cases, two EA modulators are integrated on one semiconductor substrate, and the two EA modulators are electrically connected in series to each other by an electrode (metal) formed on the substrate. In this case, the electrode connects a semiconductor layer on a lower side of one of the EA modulators and a semiconductor layer on an upper side of the other EA modulator to each other. The electrode reaches the semiconductor layer on the upper side of the other EA modulator along a side surface of a mesa structure, and causes occurrence of an inductance and a parasitic capacitance. Accordingly, this electrode has a disadvantage in high-speed operation.

Some implementations described herein include an electro-absorption modulator and an optical semiconductor device, which are excellent in high extinction ratio characteristics and high-speed operation.

In some implementations, an electro-absorption modulator includes: a semi-insulating semiconductor layer; a first electro-absorption modulator section including a first n-type semiconductor layer, a first absorption layer, and a first p-type semiconductor layer which are grown in the stated order on the semi-insulating semiconductor layer; a second electro-absorption modulator section including a second p-type semiconductor layer, a second absorption layer, and a second n-type semiconductor layer which are grown in the stated order on the semi-insulating semiconductor layer; a connection waveguide layer arranged between the first absorption layer and the second absorption layer; a first EA electrode electrically connected to the first p-type semiconductor layer and electrically connected to an outside; a second EA electrode electrically connected to the second n-type semiconductor layer and electrically connected to the outside; and a connection medium configured to electrically connect the first n-type semiconductor layer and the second p-type semiconductor layer to each other to connect the first electro-absorption modulator section and the second electro-absorption modulator section in series to each other.

### BRIEF DESCRIPTION OF THE DRAWINGS

FIG. 1 is a top view of an electro-absorption modulator according to a first example implementation of the present invention.

FIG. 2 is a schematic cross-sectional view taken along the line II-II of the electro-absorption modulator illustrated in FIG. 1.

FIG. 3A is a schematic cross-sectional view taken along the line A-A of the electro-absorption modulator illustrated in FIG. 1.

FIG. 3B is a schematic cross-sectional view taken along the line B-B of the electro-absorption modulator illustrated in FIG. 1.

FIG. 3C is a schematic cross-sectional view taken along the line C-C of the electro-absorption modulator illustrated in FIG. 1.

FIG. 4 is a top view of an optical semiconductor device according to the first example implementation.

FIG. 5 is a schematic cross-sectional view taken along the line II-II of the electro-absorption modulator illustrated in FIG. 1.

FIG. 6A is a schematic cross-sectional view taken along the line A-A of the electro-absorption modulator illustrated in FIG. 1 according to Modification Example 1.

FIG. 6B is a schematic cross-sectional view taken along the line B-B of the electro-absorption modulator illustrated in FIG. 1 according to Modification Example 1.

FIG. 6C is a schematic cross-sectional view taken along the line C-C of the electro-absorption modulator illustrated in FIG. 1 according to Modification Example 1.

FIG. 7A is a schematic cross-sectional view taken along the line A-A of the electro-absorption modulator illustrated in FIG. 1 according to Modification Example 2.

FIG. 7B is a schematic cross-sectional view taken along the line B-B of the electro-absorption modulator illustrated in FIG. 1 according to Modification Example 2.

FIG. 7C is a schematic cross-sectional view taken along the line C-C of the electro-absorption modulator illustrated in FIG. 1 according to Modification Example 2.

FIG. 8 is a schematic cross-sectional view of an electro-absorption modulator according to a second example implementation of the present invention.

FIG. 9 is a schematic cross-sectional view of the electro-absorption modulator according to the second example implementation.

FIG. 10 is a top view of an electro-absorption modulator according to a third example implementation of the present invention.

FIG. 11 is a schematic cross-sectional view taken along the line XI-XI of the electro-absorption modulator illustrated in FIG. 10.

FIG. 12A is a schematic cross-sectional view taken along the line A-A of the electro-absorption modulator illustrated in FIG. 10.

FIG. 12B is a schematic cross-sectional view taken along the line B-B of the electro-absorption modulator illustrated in FIG. 10.

FIG. 12C is a schematic cross-sectional view taken along the line C-C of the electro-absorption modulator illustrated in FIG. 10.

FIG. 13 is a top view of an electro-absorption modulator according to a fourth example implementation of the present invention.

FIG. 14A is a schematic cross-sectional view taken along the line A-A of the electro-absorption modulator illustrated in FIG. 13.

FIG. 14B is a schematic cross-sectional view taken along the line B-B of the electro-absorption modulator illustrated in FIG. 13.

FIG. 15 is a schematic cross-sectional view taken along the line E-E of the electro-absorption modulator illustrated in FIG. 13.

FIG. 16 is a top view of an electro-absorption modulator according to a fifth example implementation of the present invention.

FIG. 17 is a schematic cross-sectional view taken along the line XVII-XVII of the electro-absorption modulator illustrated in FIG. 16.

FIG. 18A is a schematic cross-sectional view taken along the line A-A of the electro-absorption modulator illustrated in FIG. 16.

FIG. 18B is a schematic cross-sectional view taken along the line B-B of the electro-absorption modulator illustrated in FIG. 16.

FIG. 18C is a schematic cross-sectional view taken along the line C-C of the electro-absorption modulator illustrated in FIG. 16.

FIG. 19 is a top view of an electro-absorption modulator according to a modification example of the fifth example implementation.

FIG. 20 is a schematic cross-sectional view taken along the line XX-XX of the electro-absorption modulator illustrated in FIG. 19 according to the modification example.

FIG. 21 is a top view of an electro-absorption modulator according to a sixth example implementation of the present invention.

FIG. 22 is a schematic cross-sectional view taken along the line A-A of the electro-absorption modulator illustrated in FIG. 21.

FIG. 23 is a schematic cross-sectional view taken along the line B-B of the electro-absorption modulator illustrated in FIG. 21.

FIG. 24 is a schematic cross-sectional view taken along the line C-C of the electro-absorption modulator illustrated in FIG. 21.

FIG. 25 is a top view of an optical semiconductor device according to the sixth example implementation.

### DETAILED DESCRIPTION

Example implementations of the present invention are specifically described in detail in the following with reference to the attached drawings. Note that, throughout the figures for illustrating the example implementations, like reference numerals are used to represent members having like functions, and a repetitive description thereof is omitted. Note that, the drawings referred to in the following are only for illustrating the example implementations by way of examples, and are not necessarily drawn to scale.

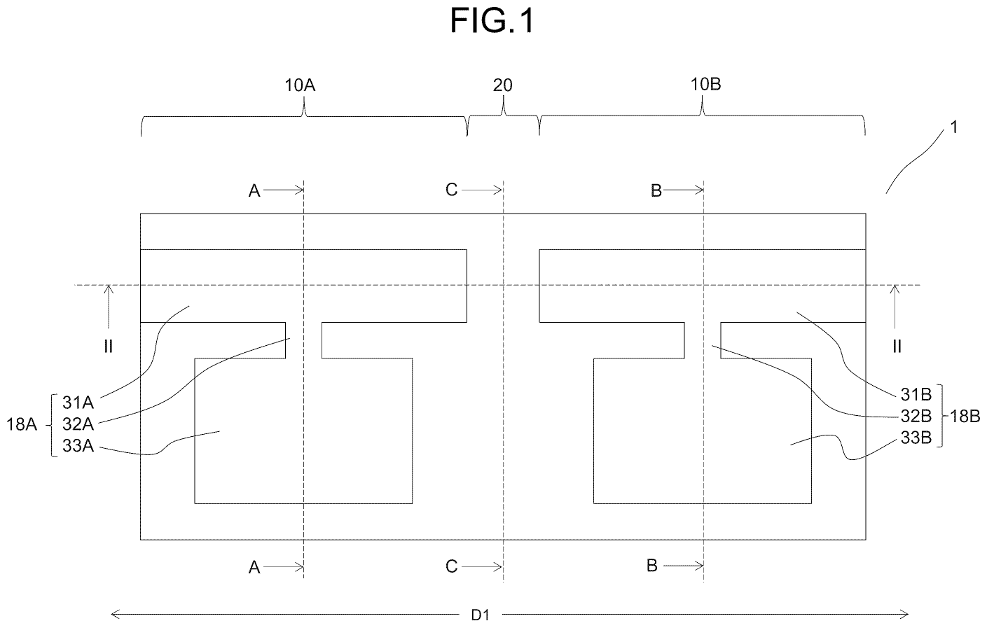

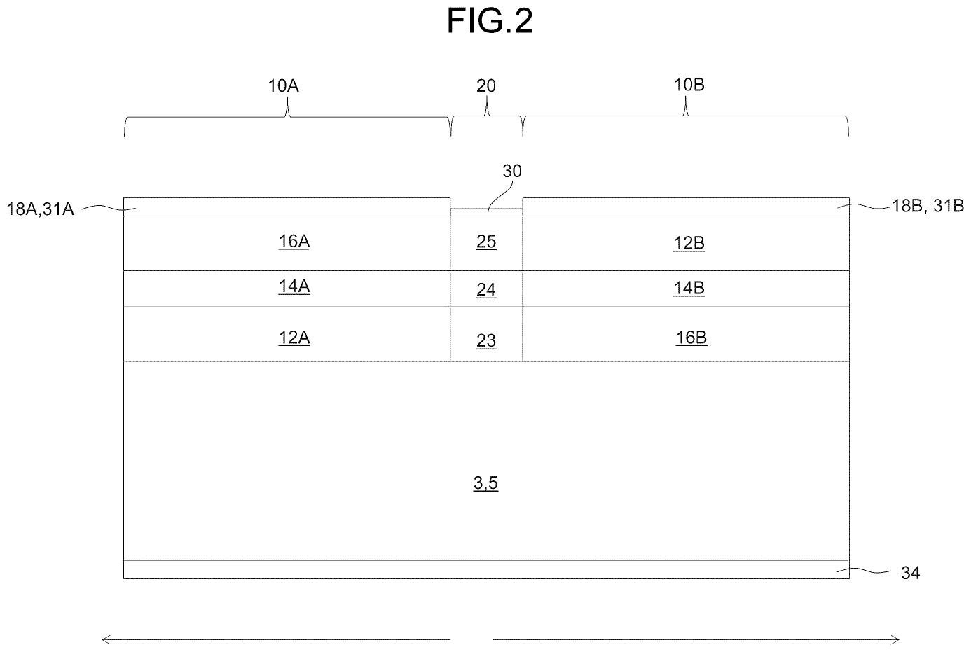

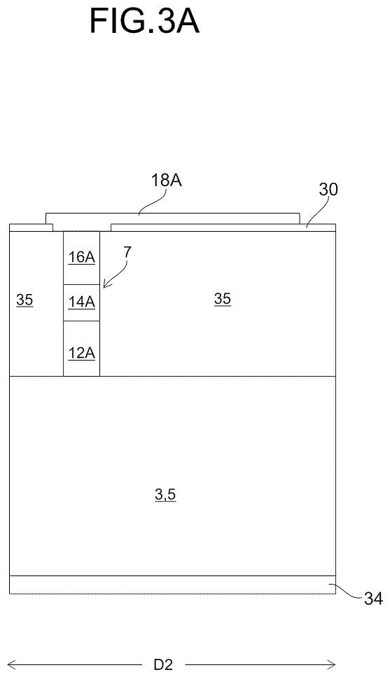

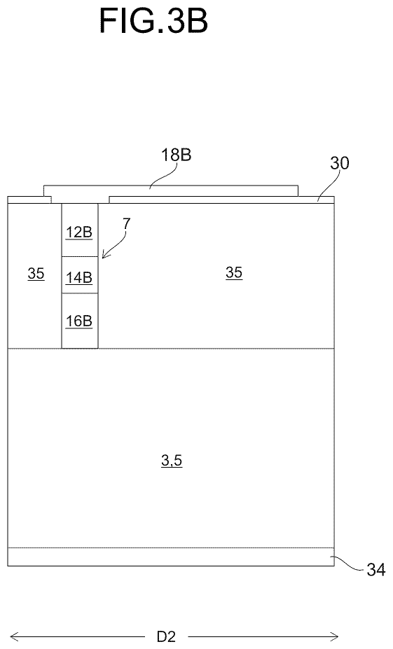

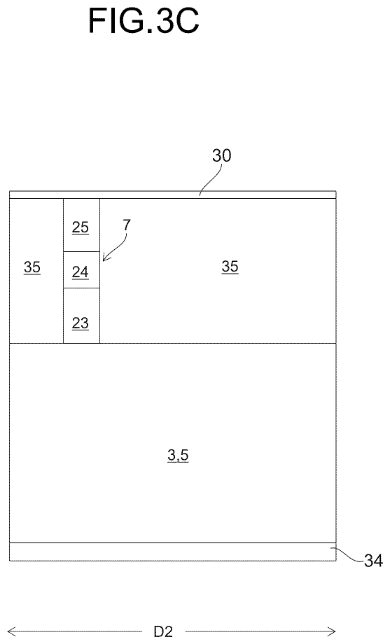

FIG. 1 is a top view of an electro-absorption modulator 1 (hereinafter abbreviated as “EA modulator 1”) according to a first example implementation of the present invention. FIG. 2 is a schematic cross-sectional view taken along the line II-II of FIG. 1. FIG. 3A is a schematic cross-sectional view taken along the line A-A of FIG. 1. FIG. 3B is a schematic cross-sectional view taken along the line B-B of FIG. 1. FIG. 3C is a schematic cross-sectional view taken along the line C-C of FIG. 1. In this case, the EA modulator 1 may be an optical semiconductor element having a function of converting light of a light source (not shown) into an optical modulated signal.

The EA modulator 1 may include a structure in which a first EA modulator section 10A, a connection waveguide section 20, and a second EA modulator section 10B are integrated on one substrate 3. The first EA modulator section 10A, the connection waveguide section 20, and the second EA modulator section 10B may be optically connected to each other through a butt-joint connection. Continuous light output from a light source (not shown) enters the EA modulator 1 from a facet on the first EA modulator section 10A side, and may be output as an optical modulated signal from a facet on the second EA modulator section 10B side. In this case, the substrate 3 may be a semi-insulating semiconductor substrate. In the following, the term “semi-insulating” indicates a state having insulating performance to the extent that substantially no current flows, as compared to a conductive semiconductor layer to be described layer. In the EA modulator 1, the first EA modulator section 10A, the connection waveguide section 20, and the second EA modulator section 10B may be arranged on a semi-insulating semiconductor layer 5. In the first example implementation, the semi-insulating semiconductor layer 5 is the substrate 3. The substrate 3 may be a conductive semiconductor substrate. In this case, it may be required to separately arrange the semi-insulating semiconductor layer 5 on the substrate 3 so that a first n-type semiconductor layer 12A to be described later and the substrate 3 are electrically isolated from each other.

The first EA modulator section 10A may include the first n-type semiconductor layer 12A, a first absorption layer 14A, and a first p-type semiconductor layer 16A which may be grown in the stated order from the semi-insulating semiconductor layer 5 side. In the following, unless particularly noted, the semiconductor layers may be grown upward from the semi-insulating semiconductor layer 5. The first n-type semiconductor layer 12A may include a plurality of semiconductor layers. The first n-type semiconductor layer 12A at least includes a cladding layer having a bandgap larger than that of the first absorption layer 14A. Further, the first n-type semiconductor layer 12A may include an optical confinement layer. The first absorption layer 14A absorbs light in response to an applied voltage. In this case, the first absorption layer 14A may be a multiple quantum well (MQW) layer of an i-type semiconductor layer that is intentionally not doped with impurities. The first absorption layer 14A may be a conductive absorption layer. The first p-type semiconductor layer 16A may include a plurality of semiconductor layers. The first p-type semiconductor layer 16A at least includes a cladding layer having a bandgap larger than that of the first absorption layer 14A. Further, the first p-type semiconductor layer 16A may include an optical confinement layer. The first p-type semiconductor layer 16A may be electrically and physically connected to a first EA electrode 18A. Details of the first EA electrode 18A are described herein. The first EA modulator section 10A may have a p-i-n structure from the first EA electrode 18A toward the semi-insulating semiconductor layer 5 side.

The second EA modulator section 10B may include a second p-type semiconductor layer 16B, a second absorption layer 14B, and a second n-type semiconductor layer 12B which may be grown in the stated order from the semi-insulating semiconductor layer 5 side. The second p-type semiconductor layer 16B may include a plurality of semiconductor layers. The second p-type semiconductor layer 16B at least includes a cladding layer having a bandgap larger than that of the second absorption layer 14B. Further, the second p-type semiconductor layer 16B may include an optical confinement layer. The second absorption layer 14B absorbs light in response to an applied voltage. In this case, the second absorption layer 14B may be a multiple quantum well (MQW) layer of an i-type semiconductor layer that is intentionally not doped with impurities. The second absorption layer 14B may be a conductive absorption layer. The second n-type semiconductor layer 12B may include a plurality of semiconductor layers. The second n-type semiconductor layer 12B at least includes a cladding layer having a bandgap larger than that of the second absorption layer 14B. Further, the second n-type semiconductor layer 12B may include an optical confinement layer. The second n-type semiconductor layer 12B may be electrically and physically connected to a second EA electrode 18B. Details of the second EA electrode 18B are described herein. The second EA modulator section 10B may have an n-i-p structure from the second EA electrode 18B toward the semi-insulating semiconductor layer 5 side.

The first absorption layer 14A and the second absorption layer 14B may have the same thickness, the same composition, and the same length in an optical axis direction. In this case, the optical axis direction may be a first direction D1 illustrated in FIG. 1. Further, the first absorption layer 14A and the second absorption layer 14B may have the same composition and the same thickness in a well layer and a barrier layer forming the multiple quantum well (MQW) layer, and also the same number of pairs of those layers. In this case, the term “same” refers to a state of being the same within a range of manufacturing variations. The well layer and the barrier layer may be formed of InGaAsP or InGaAlAs, but those materials are merely examples. The two absorption layers may have different structures.

The connection waveguide section 20 may be arranged to propagate light output from the first EA modulator section 10A to the second EA modulator section 10B. The connection waveguide section 20 may include a lower waveguide layer 23, a waveguide layer 24, and an upper waveguide layer 25 in the stated order from the semi-insulating semiconductor layer 5 side. The lower waveguide layer 23 may include a plurality of semiconductor layers. The lower waveguide layer 23 at least includes a cladding layer having a bandgap larger than that of the waveguide layer 24. Further, the lower waveguide layer 23 may include an optical confinement layer. In this case, the lower waveguide layer 23 may be an n-type semiconductor layer. The waveguide layer 24 may be a semiconductor layer having a bandgap that does not absorb propagating light. The waveguide layer 24 may be a single layer or a multilayer. For example, the waveguide layer 24 may be a bulk semiconductor layer. The upper waveguide layer 25 may include a plurality of semiconductor layers. The upper waveguide layer 25 at least may include a cladding layer having a bandgap larger than that of the waveguide layer 24. Further, the upper waveguide layer 25 may include an optical confinement layer. In this case, the upper waveguide layer 25 may be a p-type semiconductor layer.

In this case, it may be preferred that all of the cladding layers included in the first n-type semiconductor layer 12A of the first EA modulator section 10A, the second p-type semiconductor layer 16B of the second EA modulator section 10B, and the lower waveguide layer 23 of the connection waveguide section 20 comprise the same material. In this case, the phrase “the same material” refers to a material having the same semiconductor element and substantially the same composition, and the impurities added to provide conductivity or increase the insulating performance may be different. Specifically, the first n-type semiconductor layer 12A and the lower waveguide layer 23 include n-InP cladding layers. The second p-type semiconductor layer 16B may include a p-InP cladding layer. Similarly, it may be preferred that also the cladding layers included in the first p-type semiconductor layer 16A, the second n-type semiconductor layer 12B, and the upper waveguide layer 25 comprise the same material. Specifically, the first p-type semiconductor layer 16A and the upper waveguide layer 25 include p-InP cladding layers, and the second n-type semiconductor layer 12B may include an n-InP cladding layer.

The EA modulator 1 may include a mesa structure 7 as illustrated in FIG. 3A, FIG. 3B, and FIG. 3C. The first n-type semiconductor layer 12A, the first absorption layer 14A, and the first p-type semiconductor layer 16A of the first EA modulator section 10A may be included in the mesa structure 7. Similarly, the second p-type semiconductor layer 16B, the second absorption layer 14B, and the second n-type semiconductor layer 12B of the second EA modulator section 10B may be included in the mesa structure 7. Similarly, the lower waveguide layer 23, the waveguide layer 24, and the upper waveguide layer 25 of the connection waveguide section 20 may be included in the mesa structure 7. A part of the semi-insulating semiconductor layer 5 (in this case, the substrate 3) may be included in the mesa structure 7. No mesa structure 7 may be arranged at a center of the EA modulator 1 (in plan view, a center in a second direction D2, which is a direction perpendicular to the optical axis), and the mesa structure 7 may be arranged closer to one side as illustrated in FIG. 1, FIG. 3A, FIG. 3B, and FIG. 3C. However, the present invention is not limited thereto, and the mesa structure 7 may be arranged at a middle portion.

A buried layer 35 may be arranged on both sides of the mesa structure 7. The buried layer 35 may be any of a semi-insulating semiconductor layer, a multilayer structure of n-type and p-type semiconductor layers, or a combination thereof. In this case, the buried layer 35 may be formed of semi-insulating Fe-InP.

An insulating film 30 may be arranged on an upper surface of the EA modulator 1. The insulating film 30 may be arranged except for portions above the mesa structure 7 of the first EA modulator section 10A and the second EA modulator section 10B. The insulating film 30 may be arranged on an upper surface of the upper waveguide layer 25 of the connection waveguide section 20 and an upper surface of the buried layer 35.

A back surface electrode 34 may be widely arranged on a back surface of the substrate 3. The back surface electrode 34 is not an electrode for operating the EA modulator 1, but may be used as an adhesion electrode at the time of mounting the EA modulator 1 with solder to a mounting substrate such as a submount. Accordingly, the back surface electrode 34 is not required to be provided when adhesion is performed without using solder or when mounting is performed with the first EA electrode 18A side and the second EA electrode 18B side being directed to the submount, for example.

The first EA electrode 18A may include a first mesa electrode 31A arranged at a portion above the mesa structure 7, a first EA pad electrode 33A arranged at a portion above the buried layer 35, and a first bridge electrode 32A connecting the first mesa electrode 31A and the first EA pad electrode 33A to each other. Those electrodes may be integrally formed. Similarly, the second EA electrode 18B may include a second mesa electrode 31B arranged at a portion above the mesa structure 7, a second EA pad electrode 33B arranged at a portion above the buried layer 35, and a second bridge electrode 32B connecting the second mesa electrode 31B and the second EA pad electrode 33B to each other. Those electrodes may be integrally formed.

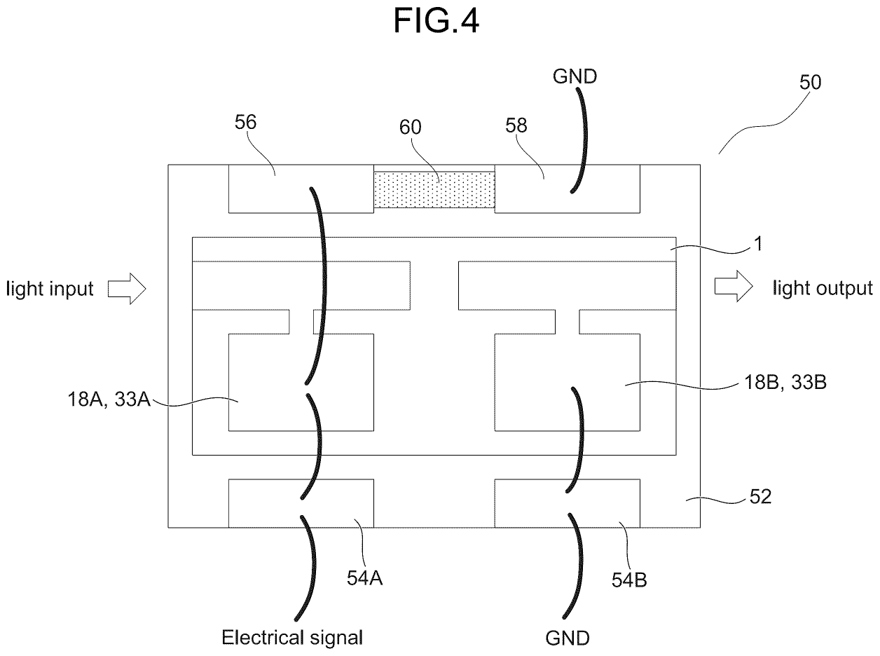

FIG. 4 is a top view of an optical semiconductor device 50 in which the EA modulator 1 is mounted on a submount 52. The EA modulator 1 may be fixed to the submount 52 on the back surface electrode 34 side. The submount 52 may include a plurality of pads. The pads and the EA modulator 1 may be connected to each other by wires. Specifically, the submount 52 may include a first pad 54A, a second pad 54B, a third pad 56, and a fourth pad 58. In this case, the pads referred to here may be electrode wiring lines provided on the submount 52, and function as transmission lines as well. A high-frequency electrical signal may be input to the first pad 54A from the outside. The first pad 54A may be connected to the first EA pad electrode 33A of the EA modulator 1 by a wire. Moreover, the first EA pad 33A may be connected to the third pad 56 by a wire. The second pad 54B may be connected to the second EA pad electrode 33B by a wire. Further, the second pad 54B may be connected to a reference potential, in this case, a ground potential. A matching resistor 60 may be arranged between the third pad 56 and the fourth pad 58 in order to improve impedance matching with an external electrical circuit. The matching resistor 60 has, for example, 50Ω. The fourth pad 58 may be connected to the ground potential. That is, the matching resistor 60 may be electrically connected in parallel to the EA modulator 1. The electrical signal applied to the first pad 54A may be a negative-bias high-frequency signal. Needless to say, an equivalent state can be obtained even when a positive-bias electrical signal is applied to the second pad 54B and the first pad 54A is used as a reference potential.

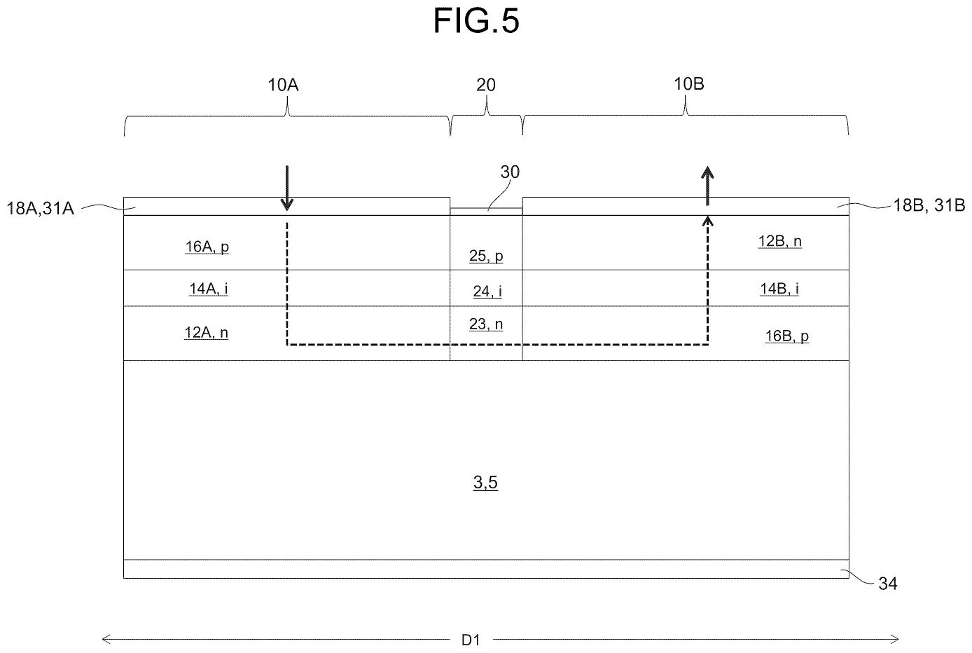

FIG. 5 shows, by the dotted line, a schematic representation of a transmission path of the electrical signal (high-frequency signal) applied between the first EA electrode 18A and the second EA electrode 18B. The path indicated by the dotted line may be a path through which the current flows most. The applied voltage may be applied between the first p-type semiconductor layer 16A and the first n-type semiconductor layer 12A of the first EA modulator section 10A, and the first absorption layer 14A absorbs light. Moreover, the electrical signal may be transmitted to the second p-type semiconductor layer 16B of the second EA modulator section 10B via the lower waveguide layer 23 of the connection waveguide section 20. Then, the voltage may be applied between the second p-type semiconductor layer 16B and the second n-type semiconductor layer 12B, and the second absorption layer 14B absorbs light. The electrical signal may be a high-frequency signal, and hence the EA modulator 1 generates a high-frequency optical signal corresponding to the high-frequency electrical signal.

The transmission path of the electrical signal indicated by the dotted line may be a path in which a voltage (negative bias) is applied in a p-i-n direction in both of the first EA modulator section 10A and the second EA modulator section 10B. In addition, the two modulator sections may be brought to a state of being electrically connected in series to each other by the lower waveguide layer 23 of the waveguide section. That is, in this case, the lower waveguide layer 23 may be a connection medium for electrically connecting the two EA modulator sections in series to each other. In this case, as viewed in the transmission direction of the electrical signal, the lower waveguide layer 23 and the second p-type semiconductor layer 16B may be connected in np connection. In this case, the drive bias is a negative bias, and hence an interface of this connection is a forward direction interface through which a current flows. Accordingly, the lower waveguide layer 23 functions as the connection medium. In this case, the lower waveguide layer 23 may be referred to as a “connection semiconductor layer.”In some cases, the two modulators both have a p-i-n structure as viewed from the electrode on the front surface side. Accordingly, in order to electrically connect the first modulator and the second modulator in series to each other, it is required to connect the lowermost layer (n-type layer) of the first modulator and the uppermost layer (p-type layer) of the second modulator to each other. An electrode is used for this connection, but this electrode is three-dimensionally arranged so as to extend from the lower side of the mesa structure to the upper side of the mesa structure. There is a fear of occurrence of a parasitic capacitance between a side surface of the mesa structure and this electrode. Further, the wiring length is long, and hence there is also a fear of occurrence of a parasitic inductance component. This structure leads to degradation of high-frequency characteristics. In contrast, in the first example implementation, the connection medium (lower waveguide layer 23) is not a structure that extends from the lower side to the upper side of the mesa structure 7 along the side surface of the mesa structure 7. In other words, it may be said that the lower waveguide layer 23 is a connection medium arranged planarly. Accordingly, the two EA modulator sections can be electrically connected in series to each other without occurrence of a large parasitic inductance or parasitic capacitance, while the influence on the high-frequency characteristics is suppressed.

The reason why this effect can be obtained is as follows. The first EA modulator section 10A having a p-i-n structure as viewed from the first EA electrode 18A side and the second EA modulator section 10B having an n-i-p structure as viewed from the second EA electrode 18B side are integrated on the substrate. Moreover, the connection medium (lower waveguide layer 23) arranged planarly electrically connects the first EA modulator section 10A and the second EA modulator section 10B in series to each other.

Further, the incident light is not entirely absorbed by the first EA modulator section 10A. The light that has not been absorbed by the first EA modulator section 10A is transmitted to the second EA modulator section 10B and absorbed by the second EA modulator section 10B. The total amount of light absorbed by the two EA modulator sections is proportional to the extinction ratio. Meanwhile, the parasitic capacitance of the EA modulator 1 is a total capacitance of the first EA modulator section 10A and the second EA modulator section 10B. In this case, when the capacitance of the first EA modulator section 10A and the capacitance of the second EA modulator section 10B are defined as C1 and C2, respectively, the parasitic capacitance of the entire EA modulator 1 is C1×C2/(C1+C2). In this case, the first EA modulator section 10A and the second EA modulator section 10B have the same modulator length and the same semiconductor structure. Thus, C1=C2 is satisfied. Accordingly, the parasitic capacitance of the entire EA modulator 1 is C1/2. Meanwhile, when the same extinction ratio is obtained by one EA modulator, the modulator length of the EA modulator is required to be a length twice as long as that of the first EA modulator section 10A. At this time, the parasitic capacitance is 2×C1. That is, in the first embodiment, with the same extinction ratio, the parasitic capacitance can be reduced to 1/4, and the operation is allowed at a higher speed. Further, no long wiring or long electrode is arranged between the first EA modulator section 10A and the second EA modulator section 10B, and hence occurrence of the parasitic capacitance or parasitic inductance between the two modulators can be suppressed. The first EA modulator section 10A and the second EA modulator section 10B are not always required to have the same modulator length. However, from the viewpoint of manufacture, it is preferred that the first EA modulator section 10A and the second EA modulator section 10B have the same semiconductor multilayer structure. In a case of an extinction ratio at a certain drive voltage in a structure having a length twice as long as that of the first EA modulator section 10A in one EA modulator, the drive voltage is doubled to obtain an equivalent extinction ratio in the first embodiment.

In this case, the voltage may also be applied through a path other than the dotted line.

For example, a transmission path from the first p-type semiconductor layer 16A via the upper waveguide layer 25 (p-type) to the second n-type semiconductor layer 12B is also conceivable. However, this path has pn connection, and causes reverse bias drive in negative bias drive. Thus, almost no current flows. Further, those three upper layers are layers that do not absorb light, and do not contribute to generation of the optical modulated signal. In order to further block the current in this path, the upper waveguide layer 25 may be a high-resistance semiconductor layer instead of being a conductive semiconductor layer. For example, impurities such as Fe-InP may be added so that a semi-insulating semiconductor layer is achieved. Besides, protons may be injected in the conductive semiconductor layer so that a high resistance is achieved. Moreover, a method of increasing the resistance by reducing a layer thickness of the upper waveguide layer 25 in the stacking direction is also conceivable. In this case, the phrase “high resistance” means that the resistance is higher than that of at least the first p-type semiconductor layer 16A.

In order to obtain the effects of the present invention, there is no limitation on the length of the connection waveguide section 20 in the first direction D1. However, when the length is excessively short, there is a fear of occurrence of a parasitic capacitance component between the first EA electrode 18A and the second EA electrode 18B (in particular, between the first mesa electrode 31A and the second mesa electrode 31B). Further, when the length is excessively long, the resistance of the lower waveguide layer 23 is increased, and there is a possibility of causing voltage drop to affect the extinction ratio characteristics. Accordingly, it is preferred that the length of the connection waveguide section 20 in the first direction D1 be 30 μm or more and 100μm or less.

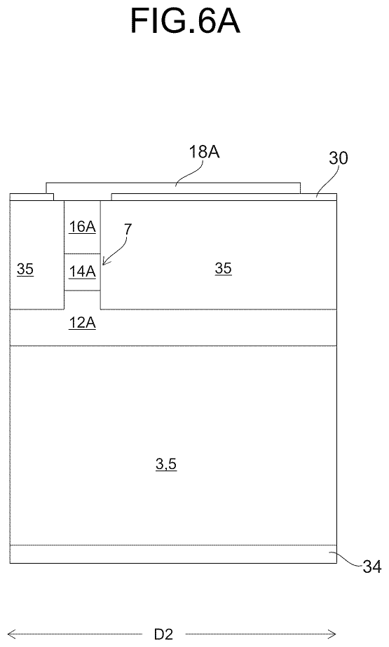

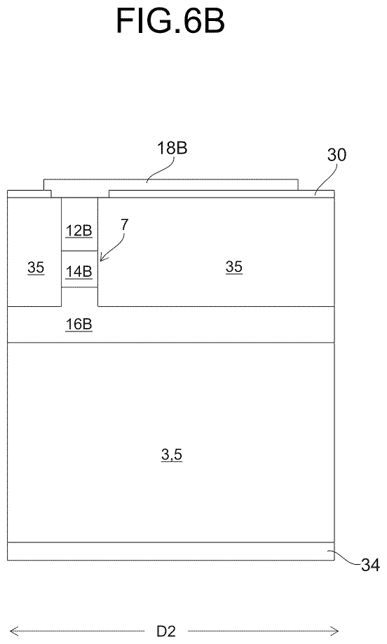

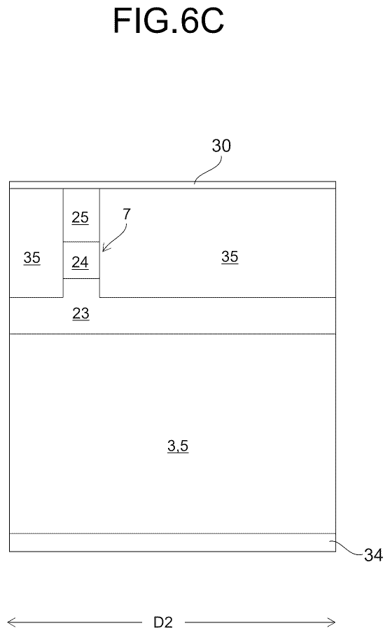

FIG. 6A, FIG. 6B, and FIG. 6C are schematic cross-sectional views of the EA modulator 1 according to Modification Example 1 of the first example implementation. FIG. 6A, FIG. 6B, and FIG. 6C are cross-sectional views corresponding to FIG. 3A, FIG. 3B, and FIG. 3C in the first example implementation, respectively.

Modification Example 1 is different from the first example implementation in that the first n-type semiconductor layer 12A, the second p-type semiconductor layer 16B, and the lower waveguide layer 23 may be arranged on the lower side of the buried layer 35. A part of each of the layers forms a lower layer of the mesa structure 7. However, those three layers are not required to be included in the mesa structure 7.

The connection medium for electrically connecting the first EA modulator section 10A and the second EA modulator section 10B to each other may be the lower waveguide layer 23 similarly to the first example implementation. In the first example implementation, the lower waveguide layer 23 may be included in the mesa structure 7. In this case, when a direction perpendicular to the optical axis in plan view is defined as the second direction D2, a width of the mesa structure 7 in the second direction D2 (mesa width) may be several micrometers. Accordingly, the lower waveguide layer 23 has a resistance to some extent, and there is a fear that a sufficient extinction ratio cannot be obtained due to the drop of the applied voltage. In contrast, in Modification Example 1, the lower waveguide layer 23 may be spread below the mesa structure 7, and the resistance may be reduced as compared to the case of the first example implementation. Accordingly, the voltage drop may be reduced, and a higher extinction ratio may be obtained under the same drive voltage.

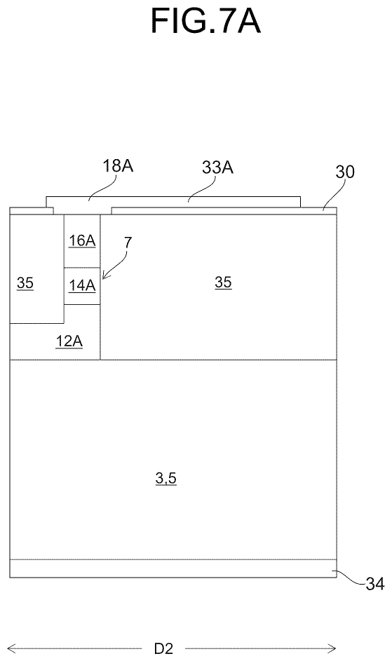

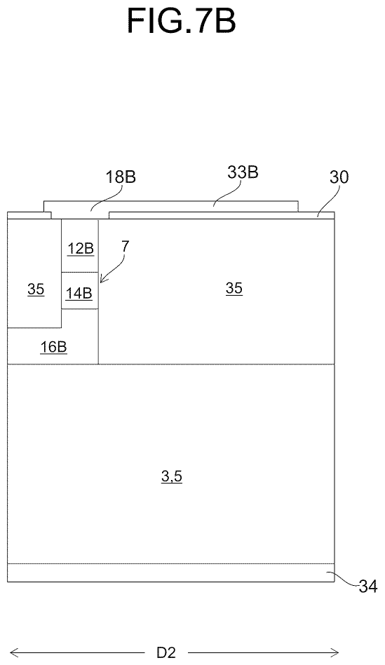

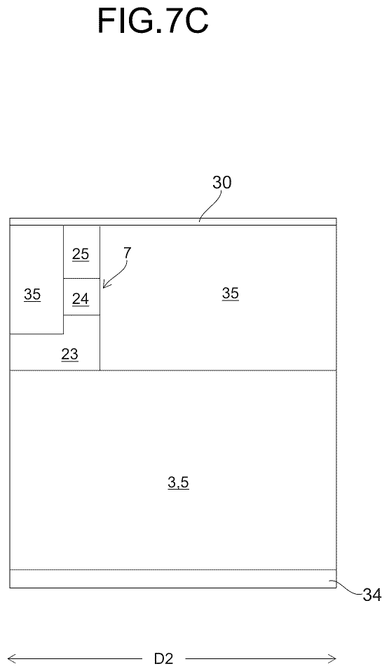

FIG. 7A, FIG. 7B, and FIG. 7C are schematic cross-sectional views of the EA modulator 1 according to Modification Example 2 of the first example implementation. FIG. 7A, FIG. 7B, and FIG. 7C are cross-sectional views corresponding to FIG. 3A, FIG. 3B, and FIG. 3C in the first example implementation, respectively.

The shapes of the first n-type semiconductor layer 12A, the second p-type semiconductor layer 16B, and the lower waveguide layer 23 in Modification Example 2 are different from those in Modification Example 1. In Modification Example 2, those three layers do not reach the side surface of the EA modulator 1 on one side of the mesa structure 7 in the second direction D2. Specifically, as illustrated in FIG. 7A, the first n-type semiconductor layer 12A is not arranged at a position overlapping the first EA pad electrode 33A in plan view.

Similarly, as illustrated in FIG. 7B, the second p-type semiconductor layer 16B is not arranged at a position overlapping the second EA pad electrode 33B in plan view. The lower waveguide layer 23 may have the same width as that of the first n-type semiconductor layer 12A and the second p-type semiconductor layer 16B in the second direction D2.

Below the first EA pad electrode 33A in Modification Example 1, the first n-type semiconductor layer 12A may be arranged across the buried layer 35. In this case, a voltage may be applied between the first EA pad electrode 33A and the first n-type semiconductor layer 12A, and hence a parasitic capacitance corresponding to the size of the first EA pad electrode 33A may be caused. The parasitic capacitance inhibits high-speed operation. In Modification Example 2, no first n-type semiconductor layer 12A is arranged below the first EA pad electrode 33A, and the semi-insulating semiconductor layer 5 is arranged instead. Accordingly, a parasitic capacitance due to the first EA pad electrode 33A is not caused or is very small. Accordingly, the EA modulator 1 according to Modification Example 2 is excellent in high-speed responsiveness. Similar effects can be obtained also in the second EA pad electrode 33B.

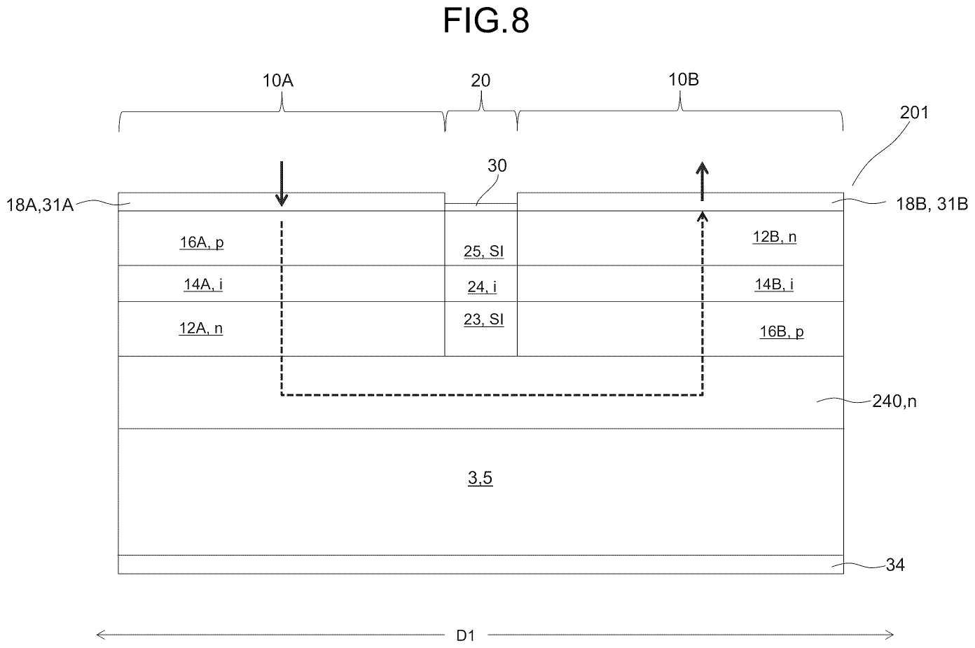

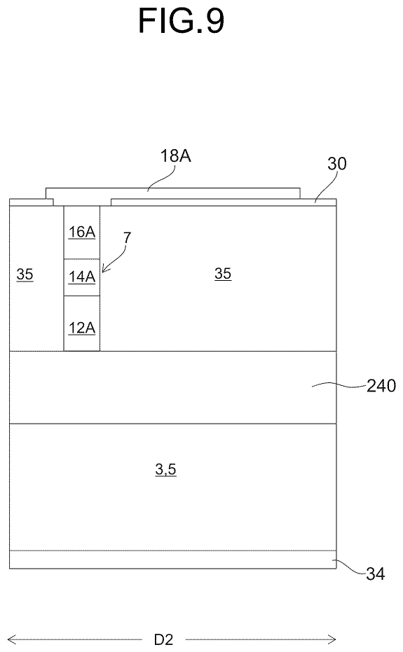

FIG. 8 is a schematic cross-sectional view of an EA modulator 201 according to a second example implementation of the present invention, and corresponds to FIG. 5 in the first example implementation. FIG. 9 is a schematic cross-sectional view taken along a direction perpendicular to the mesa structure 7 of the first EA modulator section 10A, and corresponds to FIG. 3A. The second example implementation is different from the first example implementation in that a spacer layer 240 is arranged between the substrate 3 and each of the first n-type semiconductor layer 12A, the second p-type semiconductor layer 16B, and the lower waveguide layer 23. Further, the second example implementation is different from the first example implementation in that the lower waveguide layer 23 and the upper waveguide layer 25 of the connection waveguide section 20 are semi-insulating semiconductor layers. Cross sections taken along the direction perpendicular to the mesa structure 7 of the second EA modulator section 10B and the connection waveguide section 20 (corresponding to FIG. 9) may be the same as the cross-sectional view of the first EA modulator section 10A, although the layers included in the mesa structure 7 may be different.

The spacer layer 240 may be an n-type semiconductor layer. In this case, the spacer layer 240 may comprise n-InP similarly to the first n-type semiconductor layer 12A. In the first example implementation, the connection medium for connecting the first EA modulator section 10A and the second EA modulator section 10B to each other may be the lower waveguide layer 23 of the connection waveguide section 20. In the second example implementation, the connection medium may be the spacer layer 240. The spacer layer 240 may be arranged on the entire surface of the substrate 3 (semi-insulating semiconductor layer 5). The spacer layer 240 may have a thickness in the stacking direction and a width in the second direction D2 which may be larger than those of the lower waveguide layer 23, and may have a resistance smaller than that of the lower waveguide layer 23. Accordingly, an electrical resistance between the first EA modulator section 10A and the second EA modulator section 10B may be reduced. FIG. 8 shows the electrical path by the dotted line similarly to FIG. 5. As illustrated in FIG. 8, the first EA modulator section 10A and the second EA modulator section 10B may be electrically connected in series to each other via the spacer layer 240 (connection medium). Further, the spacer layer 240 may not be arranged on the side surface of the mesa structure 7, and may be arranged planarly. Thus, the effects described in the first embodiment can be obtained.

In this case, the lower waveguide layer 23 may be a conductive semiconductor layer, for example, an n-type semiconductor layer. In this case, the electrical path becomes a path that passes via the lower waveguide layer 23 in addition to the spacer layer 240. Further, the spacer layer 240 may be a p-type semiconductor. However, an n-type semiconductor may have a resistance smaller than that of a p-type semiconductor, and hence it may be preferred that the spacer layer 240 be an n-type semiconductor.

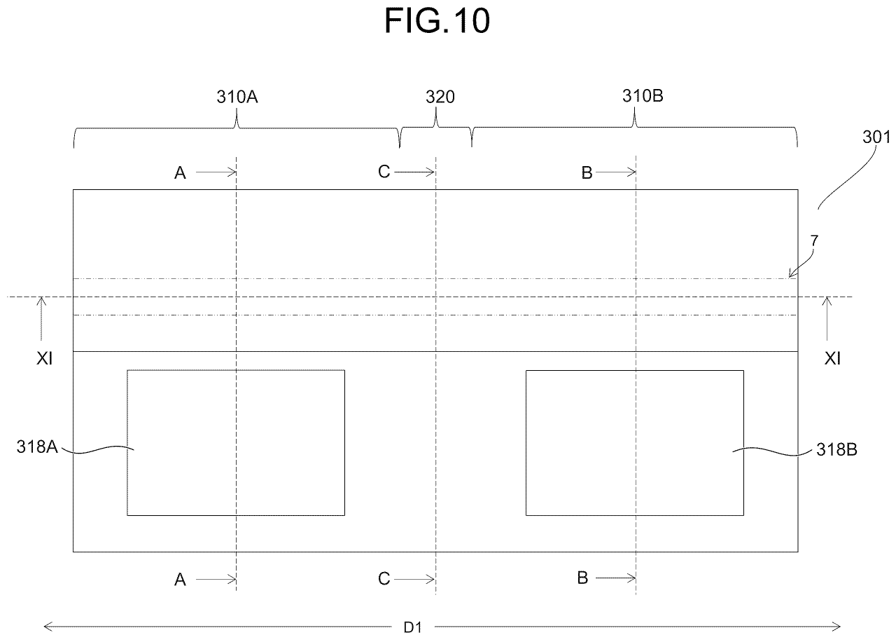

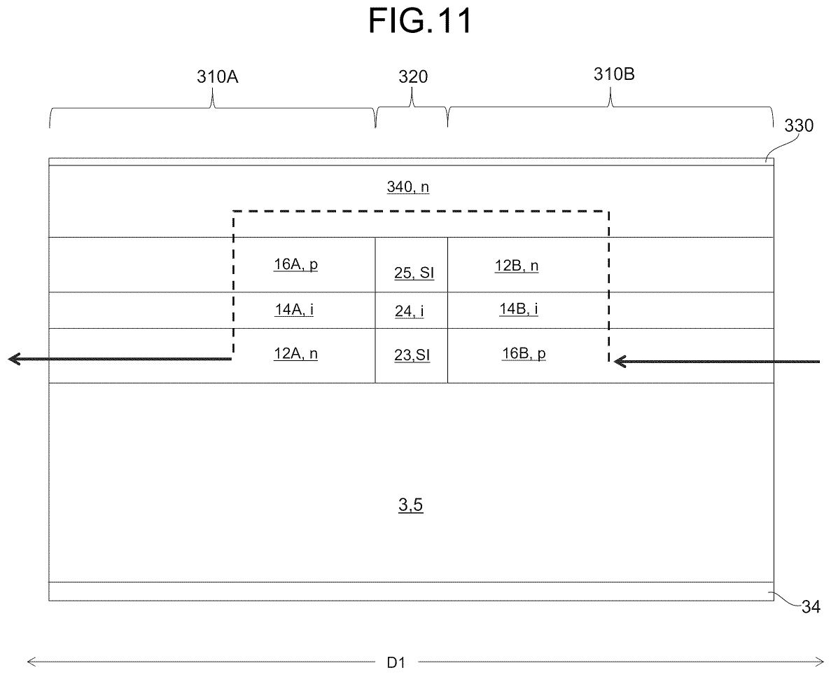

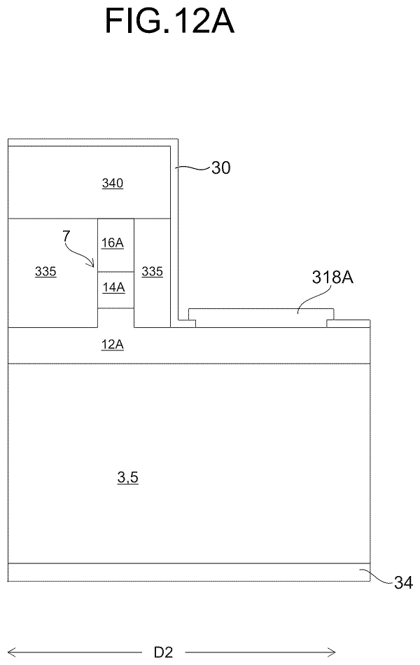

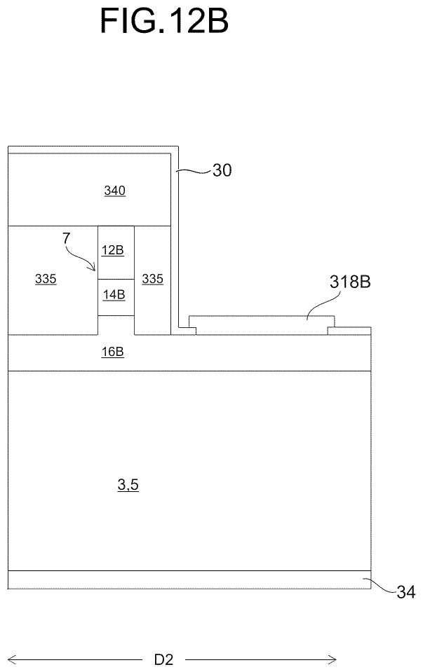

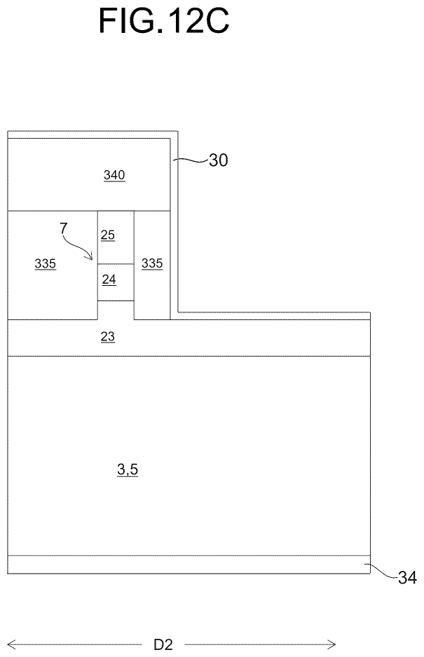

FIG. 10 is a top view of an electro-absorption modulator 301 according to a third example implementation of the present invention. FIG. 11 is a schematic cross-sectional view taken along the line XI-XI of FIG. 10. FIG. 12A is a schematic cross-sectional view taken along the line A-A of FIG. 10. FIG. 12B is a schematic cross-sectional view taken along the line B-B of FIG. 10. FIG. 12C is a schematic cross-sectional view taken along the line C-C of FIG. 10. Similarly to the EA modulators described in other example implementations, in the EA modulator 301 according to the third example implementation, a first EA modulator section 310A, a second EA modulator section 310B, and a connection waveguide section 320 arranged between the first EA modulator section 310A and the second EA modulator section 310B may be integrated to be arranged on the substrate 3.

The EA modulator 301 may include the mesa structure 7 and a buried layer 335 arranged on both side surfaces of the mesa structure 7. In FIG. 10, the position of the mesa structure 7 is indicated by the long dashed double-short dashed line. Further, a spacer layer 340 may be arranged on upper surfaces of the mesa structure 7 and the buried layer 335. In this case, the spacer layer 340 may be an n-type semiconductor layer, and is, for example, an n-InP layer. As illustrated in FIG. 12A and the like, the buried layer 335 and the spacer layer 340 do not reach the side surface of the EA modulator 301 on one side of the mesa structure.

In the first EA modulator section 310A, a first EA electrode 318A may be arranged in a region in which no buried layer 335 is arranged. The first EA electrode 318A may be formed only of a first EA pad electrode to which the electrical signal from the outside is transmitted. The first EA electrode 318A may be electrically and physically connected to the first n-type semiconductor layer 12A.

In the second EA modulator section 310B, a second EA electrode 318B may be arranged in a region in which no buried layer 335 is arranged. The second EA electrode 318B may be formed only of a second EA pad electrode to which the electrical signal from the outside is transmitted. The second EA electrode 318B may be electrically and physically connected to the second p-type semiconductor layer 16B.

The lower waveguide layer 23 and the upper waveguide layer 25 of the connection waveguide section 320 may be semi-insulating semiconductor layers. However, similarly to other example implementations, conductive semiconductor layers or semiconductor layers increased in resistance may be used.

The insulating film 30 may be arranged on the front surface of the EA modulator 301. However, no insulating film 30 may be arranged at a connection portion between the first EA electrode 318A and the first n-type semiconductor layer 12A and a connection portion between the second EA electrode 318B and the second p-type semiconductor layer 16B.

FIG. 11 shows a schematic representation of a transmission path of the electrical signal by the solid line and the dotted line similarly to FIG. 5. In this case, the connection medium for electrically connecting the first EA modulator section 310A and the second EA modulator section 310B in series to each other is the spacer layer 340. The solid line indicates the voltage applied from the outside to the first EA electrode 318A and the second EA electrode 318B. In this case, for the sake of convenience, the voltage is illustrated as being applied from the side surface (facet) of the EA modulator 301, but, in an actual case, as illustrated in FIG. 10, FIG. 12A, and FIG. 12B, the voltage is applied to the front surface side of the EA modulator 301 (front surface side of the first EA electrode 318A and the second EA electrode 318B). In the third example implementation, a negative-bias electrical signal may be input to the second EA electrode 318B, and the first EA electrode 318A may be connected to a ground potential (reference potential). Also in the third example implementation, a voltage may be applied to the two modulator sections in the p-i-n direction, and both of the modulator sections may be electrically connected in series to each other by the connection medium (spacer layer 340) arranged planarly. Thus, the above-mentioned effects can be obtained. As described above, the negative bias is not always required to be applied from a layer above the mesa structure 7, and may be applied from a layer below the mesa structure 7. It is only required that a negative-bias voltage be applied to both of the two EA modulators in the p-i-n direction.

Further, the spacer layer 340 may be a p-type semiconductor. However, an n-type semiconductor may have a resistance smaller than that of a p-type semiconductor, and hence it may be preferred that the spacer layer 340 be an n-type semiconductor.

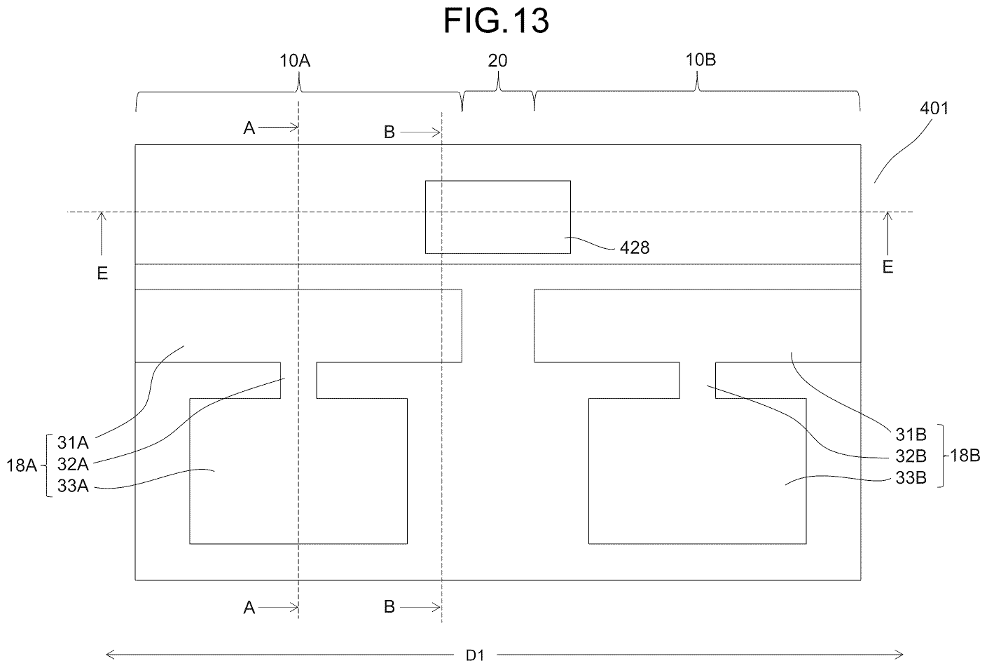

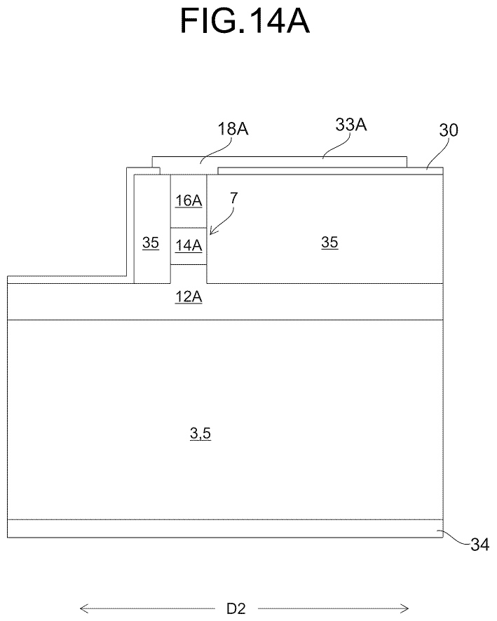

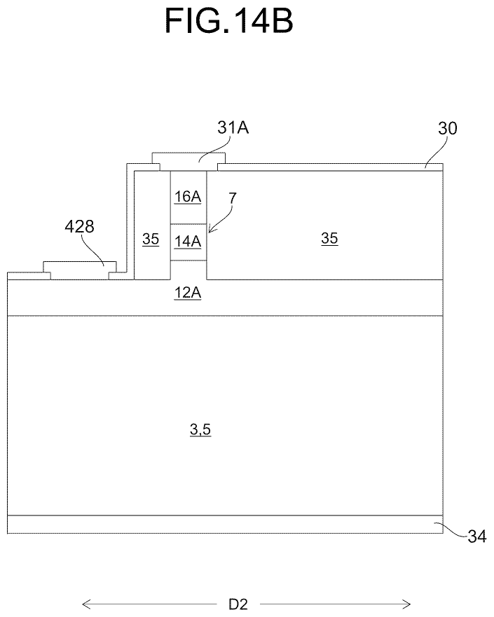

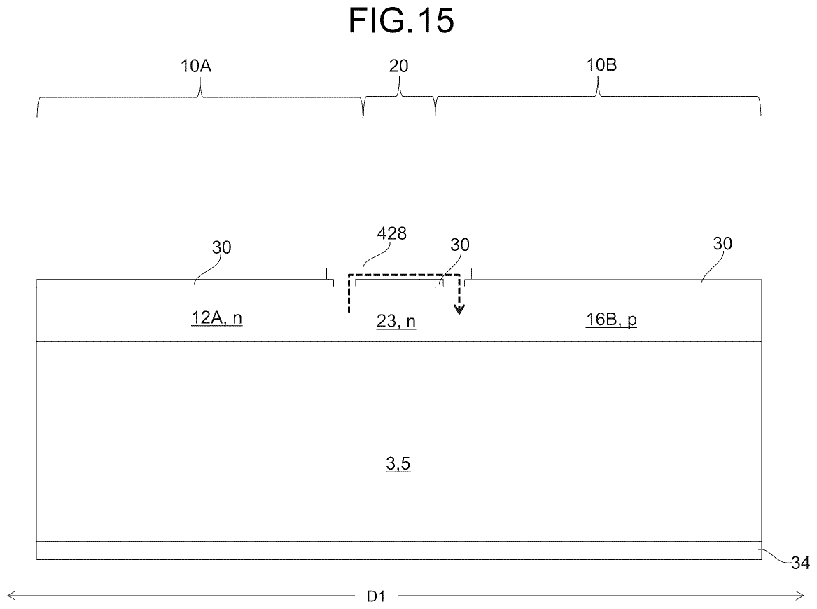

FIG. 13 is a top view of an EA modulator 401 according to a fourth example implementation of the present invention. FIG. 14A is a schematic cross-sectional view taken along the line A-A of FIG. 13. FIG. 14B is a schematic cross-sectional view taken along the line B-B of FIG. 13. FIG. 15 is a schematic cross-sectional view taken along the line E-E. FIG. 15 shows a schematic representation of a transmission path of the electrical signal via the connection medium by the dotted line.

The semiconductor multilayer of the EA modulator 401 may be the same as that of the EA modulator 1 of the first example implementation. The main differences are as follows. First, as illustrated in FIG. 14A and FIG. 14B, the buried layer 35 is not arranged up to the side surface of the EA modulator 401 on the left side of the mesa structure 7. In a region in which no buried layer 35 is arranged, a lower layer in each region (first n-type semiconductor layer 12A, second p-type semiconductor layer 16B, or lower waveguide layer 23) and the insulating film 30 may be arranged. As illustrated in FIG. 14A and FIG. 14B, no buried layer 35 is arranged in the entire region on the left side of the mesa structure 7. The buried layer 35 may be in contact with both side surfaces of the mesa structure 7. Further, a connection electrode 428 is arranged in a part of the region in which no buried layer 35 is arranged. Details of the connection electrode 428 are described herein.

Although not shown, the cross-sectional view of the mesa structure 7 taken along the first direction D1 is the same as that of FIG. 2.

The connection electrode 428 comprises a metal. In this case, the connection electrode 428 may be the connection medium. The connection electrode 428 connects the first n-type semiconductor layer 12A and the second p-type semiconductor layer 16B to each other. In the connection waveguide section 20, the insulating film 30 may be arranged between the connection electrode 428 and the lower waveguide layer 23. The insulating film 30 below the connection electrode 428 is not required to be arranged.

Similarly to the first example implementation, a negative bias may be applied to the first EA electrode 18A, and the second EA electrode 18B may be connected to the ground potential (reference potential). In the first example implementation, the first EA modulator section 10A and the second EA modulator section 10B may be electrically connected to each other via the lower waveguide layer 23 being a semiconductor, but, in the fourth example implementation, the first EA modulator section 10A and the second EA modulator section 10B may be connected in series to each other via the connection electrode 428. As described above, a semiconductor interface between the n-type lower waveguide layer 23 and the second p-type semiconductor layer 16B may be in a forward-direction bias drive state, and hence a current flows. However, the semiconductor interface may be a junction interface of semiconductors, and hence the semiconductor interface may cause voltage drop corresponding to a built-in voltage. Further, the lower waveguide layer 23 may be a semiconductor layer, and hence may have a large resistivity as compared to that of a metal being a conductor layer. In contrast, in the fourth example implementation, the first EA modulator section 10A and the second EA modulator section 10B may be connected to each other by a metal electrode, and hence the above-mentioned influence of the voltage drop can be avoided. Further, the metal electrode may be planar and may not be arranged on the side surface of the mesa structure 7, and further may have a short length. Thus, occurrence of a parasitic capacitance and a parasitic inductance can be suppressed. Accordingly, an EA modulator adapted to high-speed operation is achieved.

In this case, the lower waveguide layer 23 may be an n-type semiconductor layer similarly to the first example implementation, but the lower waveguide layer 23 may be a semi-insulating semiconductor layer.

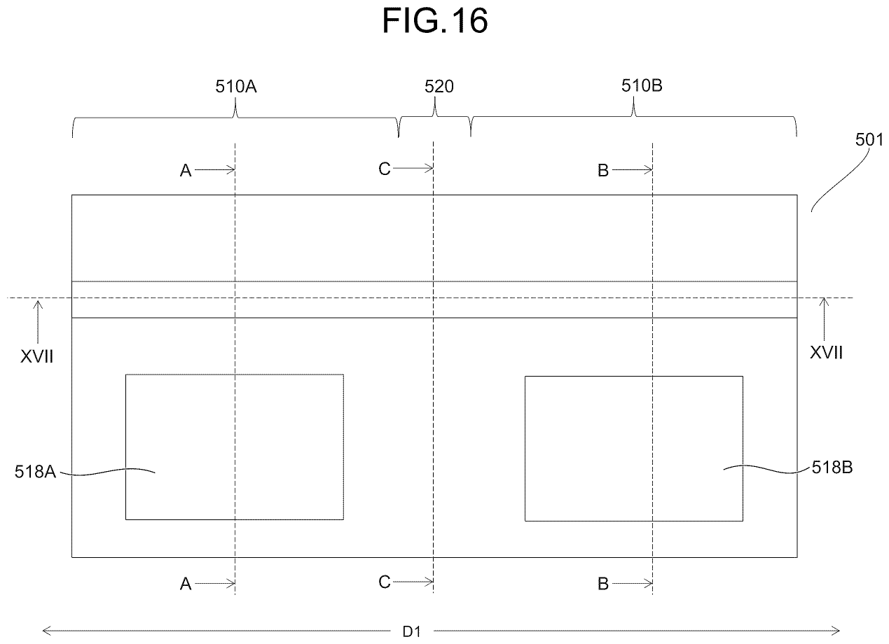

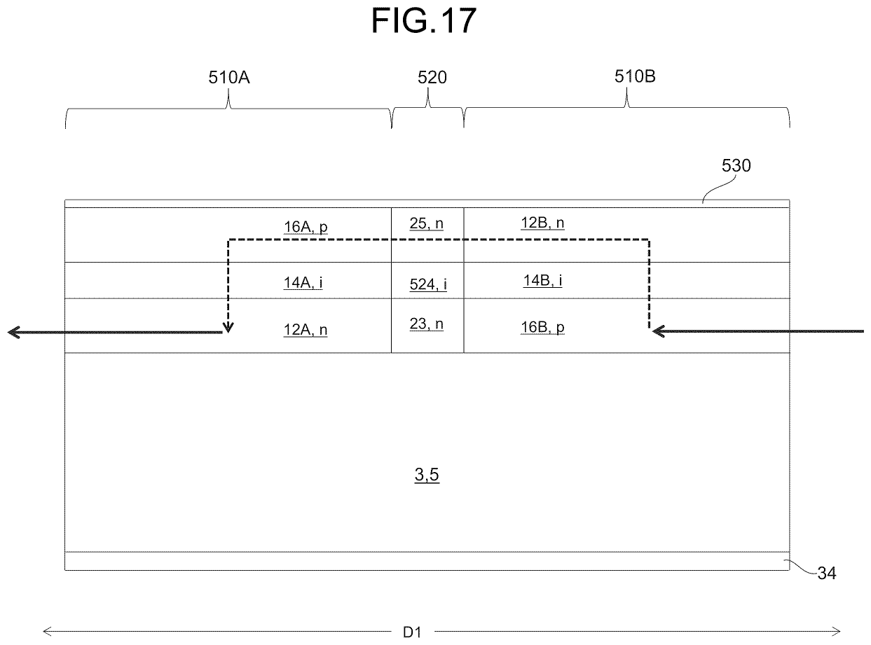

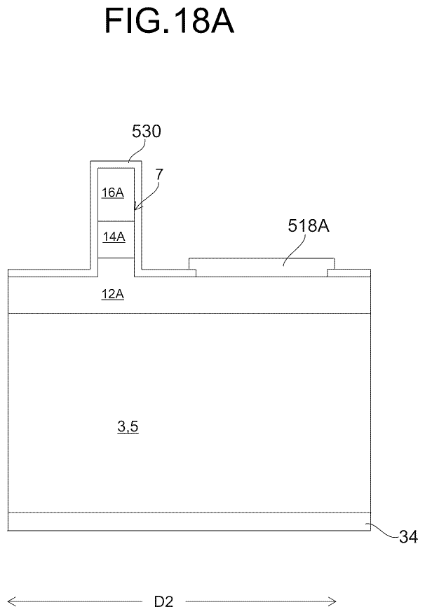

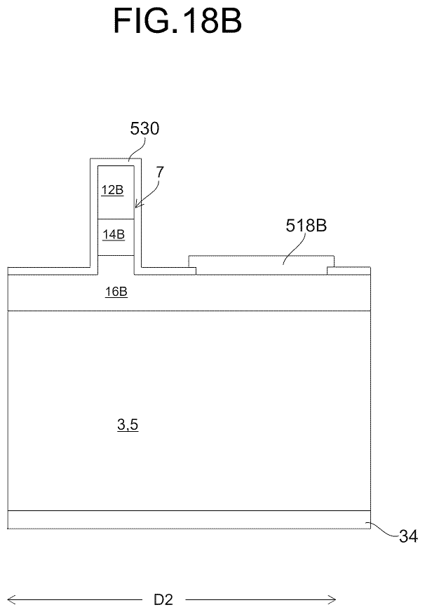

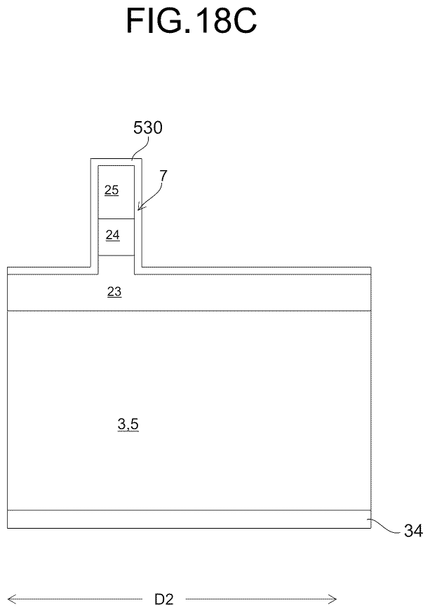

FIG. 16 is a top view of an EA modulator 501 according to a fifth example implementation of the present invention. FIG. 17 is a schematic cross-sectional view taken along the line XVII-XVII of FIG. 16. FIG. 18A, FIG. 18B, and FIG. 18C are schematic cross-sectional views taken along the line A-A, the line B-B, and the line C-C of FIG. 16, respectively.

In the fifth example implementation, unlike other example implementations, the buried layer 35 is not arranged on the side surface of the mesa structure 7. An insulating film 530 may be arranged on the side surface of the mesa structure 7.

In a first EA modulator section 510A, a first EA electrode 518A may be arranged in a region separated from the mesa structure 7. The first EA electrode 518A may be formed only of a first EA pad electrode to which the electrical signal from the outside is transmitted. The first EA electrode 518A may be electrically and physically connected to the first n-type semiconductor layer 12A.

In a second EA modulator section 510B, a second EA electrode 518B may be arranged in a region separated from the mesa structure 7. The second EA electrode 518B may be formed only of a second EA pad electrode to which an electrical signal from the outside may be transmitted. The second EA electrode 518B may be electrically and physically connected to the second p-type semiconductor layer 16B.

The lower waveguide layer 23 and the upper waveguide layer 25 of a connection waveguide section 520 may be n-type semiconductor layers.

FIG. 17 shows a schematic representation of a transmission path of the electrical signal by the solid line and the dotted line similarly to FIG. 5. In this case, the connection medium for electrically connecting the first EA modulator section 510A and the second EA modulator section 510B in series to each other may be the upper waveguide layer 25 of the connection waveguide section 520. That is, the upper waveguide layer 25 may be the connection semiconductor layer. The solid line indicates a voltage applied from the outside to the first EA electrode 518A and the second EA electrode 518B. In this case, for the sake of convenience, the voltage may be illustrated as being applied from the side surface (facet) of the EA modulator 501, but, in an actual case, as illustrated in FIG. 16, FIG. 18A, and FIG. 18B, the voltage may be applied from the front surface side of the EA modulator 501 (front surface side of the first EA electrode 518A and the second EA electrode 518B). In the fifth example implementation, a negative-bias electrical signal may be input to the second EA electrode 518B, and the first EA electrode 518A may be connected to the ground potential (reference potential). Also in the fifth example implementation, a voltage may be applied to the two modulator sections in the p-i-n direction, and both of the modulator sections may be electrically connected in series to each other by the connection medium (upper waveguide layer 25) arranged planarly. Thus, the above-mentioned effects can be obtained.

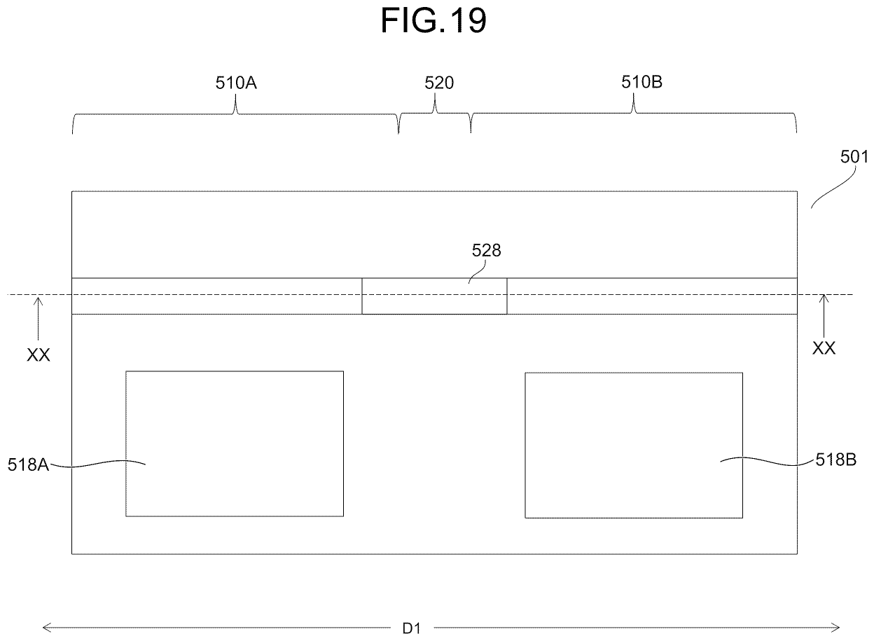

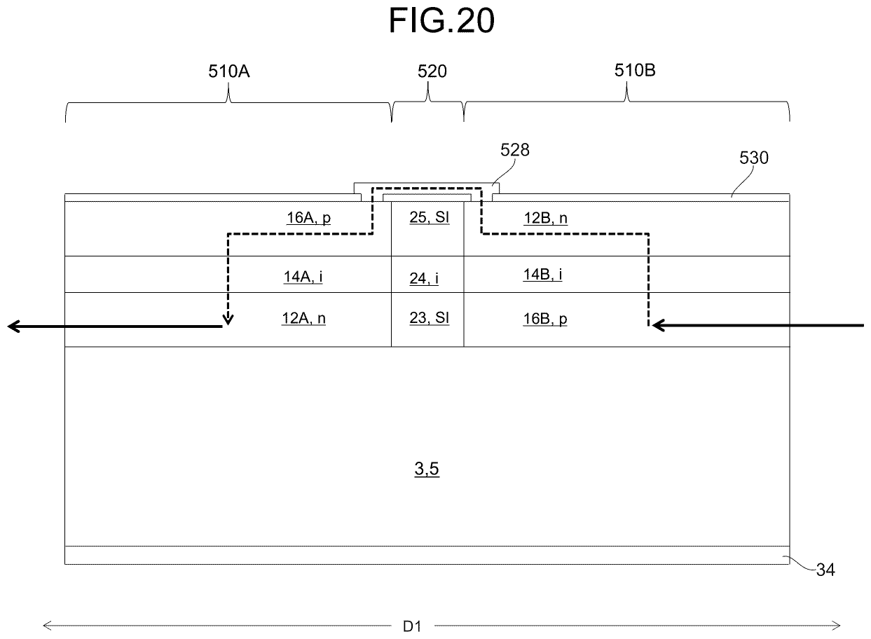

FIG. 19 is a top view of an EA modulator 501 according to a modification example of the fifth example implementation. FIG. 20 is a schematic cross-sectional view taken along the line XX-XX of FIG. 19. The difference from the fifth example implementation resides in that a connection electrode 528 is arranged and in the polarity of the semiconductor layers of the connection waveguide section 520.

As illustrated in FIG. 20, the connection electrode 528 connects the first p-type semiconductor layer 16A and the second n-type semiconductor layer 12B to each other. The connection electrode 528 may be arranged on the upper surface of the mesa structure 7. The connection electrode 528 may comprise a metal.

The lower waveguide layer 23 and the upper waveguide layer 25 of the connection waveguide section 520 may be semi-insulating semiconductor layers.

FIG. 20 shows a schematic representation of a transmission path of the electrical signal by the solid line and the dotted line similarly to FIG. 5. In this case, the connection medium for electrically connecting the first EA modulator section 510A and the second EA modulator section 510B in series to each other may be the connection electrode 528. With the connection electrode 528, the two modulator sections may be electrically connected in series to each other without interposing a semiconductor. This effect is the same as that described in the fourth example implementation. Further, the connection electrode 528 may be arranged only on the upper surface of the mesa structure, and may have a planar structure.

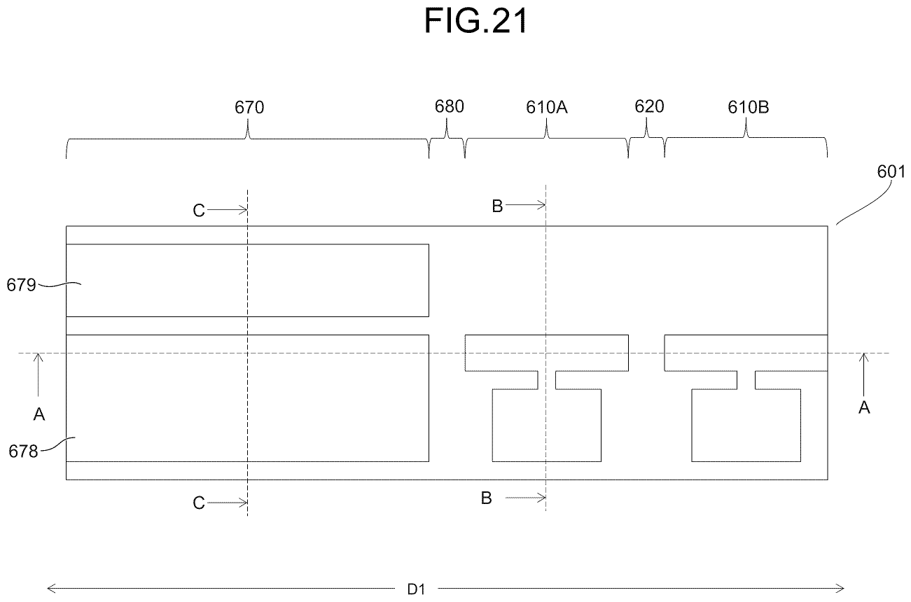

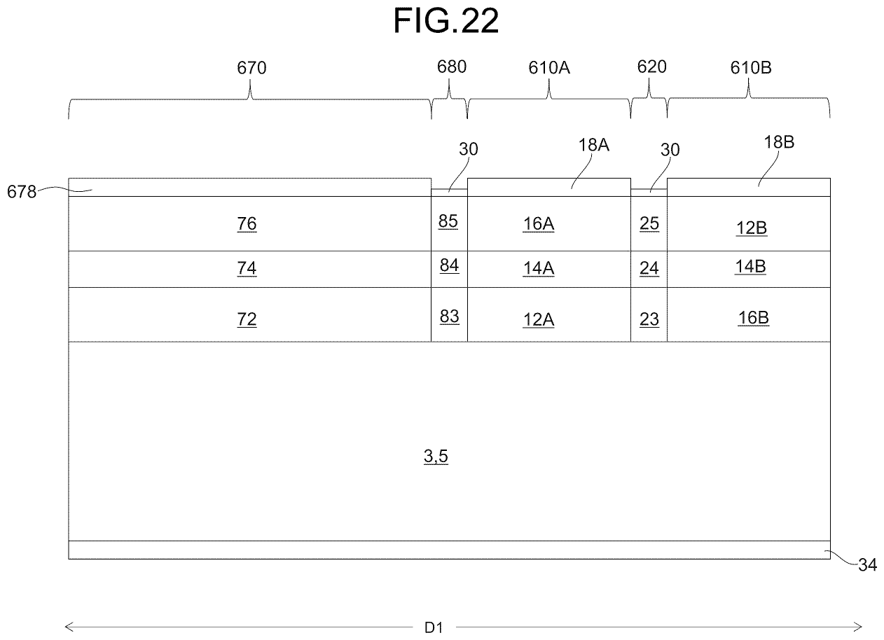

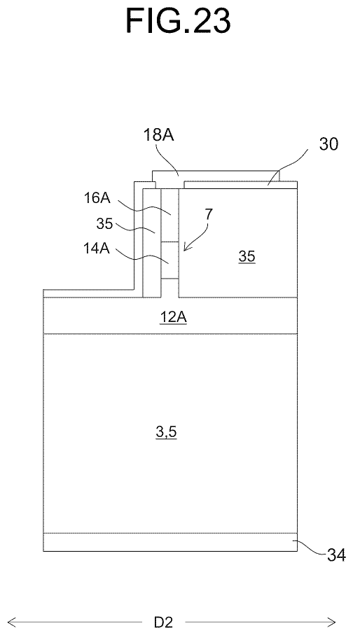

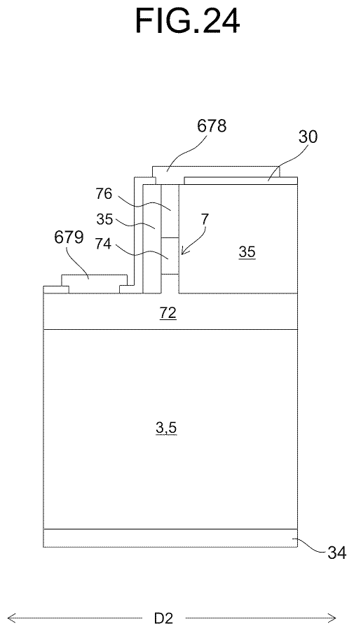

FIG. 21 is a top view of an EA modulator 601 according to a sixth example implementation of the present invention. FIG. 22 is a schematic cross-sectional view taken along the line A-A of FIG. 21. FIG. 23 is a schematic cross-sectional view taken along the line B-B of FIG. 21. FIG. 24 is a schematic cross-sectional view taken along the line C-C of FIG. 21. The electro-absorption modulator 601 may be an EA modulator integrated laser in which a semiconductor laser and an EA modulator may be integrated on the same substrate 3.

The EA modulator 601 may include a laser section 670, a second connection waveguide section 680, a first EA modulator section 610A, a connection waveguide section 620, and a second EA modulator section 610B. In this case, the first EA modulator section 610A, the connection waveguide section 620, and the second EA modulator section 610B may have the same multilayer structures as those of the EA modulator 1 described in the first example implementation. The substrate 3 may be a semi-insulating semiconductor substrate.

The laser section 670 may include an n-type laser lower cladding layer 72, an active layer 74, and a p-type laser upper cladding layer 76 in the stated order from the semi-insulating semiconductor layer 5 side (in this case, the substrate 3 side). The laser lower cladding layer 72 may include a semiconductor layer having a bandgap larger than that of the active layer 74. The laser lower cladding layer 72 may be one layer or may have a multilayer structure. The active layer 74 at least may include a multiple quantum well (MQW) layer that oscillates continuous light in response to the applied voltage. Further, the active layer may include an optical confinement layer on both upper and lower sides or one of the upper and lower sides of the multiple quantum well (MQW) layer. The laser upper cladding layer 76 may include a semiconductor layer having a bandgap larger than that of the active layer 74. The laser upper cladding layer 76 may be one layer or may have a multilayer structure. Further, the laser section 670 may include a diffraction grating layer (not shown). The laser section 670 may have a p-i-n structure from a first laser electrode 678 to be described herein toward the semi-insulating semiconductor layer 5 side.

The laser section 670 may include the first laser electrode 678 electrically connected to the laser upper cladding layer 76, and a second laser electrode 679 electrically connected to the laser lower cladding layer 72. In this case, through injection of a DC current, the laser section 670 oscillates continuous light. The first laser electrode 678 may be in contact with the p-type semiconductor layer (laser upper cladding layer 76), and hence forward bias drive in which a positive voltage is applied to the first laser electrode 678 may be obtained. The oscillated continuous light may be transmitted to the second connection waveguide section 680.

The second connection waveguide section 680 may include a second lower waveguide layer 83, a second waveguide layer 84, and a second upper waveguide layer 85 in the stated order from the semi-insulating semiconductor layer 5 side. The structure of those layers may have the same configuration as that of the connection waveguide section 620 except for the polarity. The insulating film 30 may be arranged on the surface of the second upper waveguide layer 85.

Each region may include the mesa structure 7 as illustrated in FIG. 23 and FIG. 24. The buried layer 35 may be arranged on the side surfaces of the mesa structure 7. Further, the lowermost layer of the mesa structure 7 may be formed of a part of a lower layer in each region. Further, those lower layers may be arranged widely on the semi-insulating semiconductor layer 5 (substrate 3). Further, as illustrated in FIG. 23 and FIG. 24, no buried layer 35 may be arranged in a part of a region in which no first EA electrode 18A or no first laser electrode 678 may be arranged. In the laser section 670, there may be a region in which no insulating film 30 may be arranged, and the second laser electrode 679 may be arranged in this region. The cross-sectional views taken along the second direction D2 of the connection waveguide section 620 and the second EA modulator section 610B may be substantially the same as that of FIG. 23 except for the point that the multilayer structure may be different.

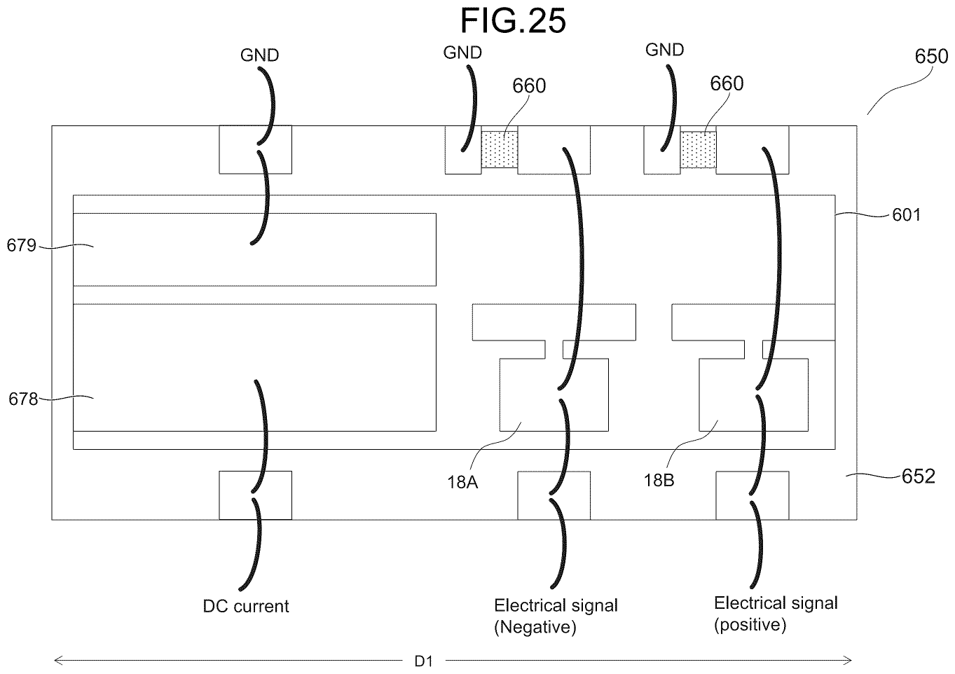

FIG. 25 is a top view of an optical semiconductor device 650 in which the EA modulator 601 is mounted on a submount 652. The EA modulator 601 may be fixed to the submount 652 on the back surface electrode 34 side. A DC current may be injected to the first laser electrode 678 of the laser section 670 via a pad on the submount 652. The second laser electrode 679 may be connected to the ground potential. Differential electrical signal may be respectively applied to the first EA modulator section 610A and the second EA modulator section 610B. The differential electrical signals may be a pair of electrical signals formed of a positive phase signal and a reverse phase signal. In this case, the reverse phase signal may be applied to the first EA modulator section 610A, and the positive phase signal may be applied to the second EA modulator section 610B. Further, in this case, the reverse phase signal may be a negative bias, and the positive phase signal may be a positive bias. Further, each of the EA modulator sections may be electrically connected in parallel to a matching resistor 660.

The differential electrical signals can have amplitudes that are half of an amplitude of a high-frequency electrical signal as compared to single-ended drive illustrated in FIG. 4. In the present invention, the parasitic capacitance is reduced by reducing the modulator length. However, the modulator length is reduced, and hence a resistance is increased and a drive amplitude required for obtaining the same extinction ratio is increased. However, through differential signal drive, the extinction ratio can be ensured without increasing the drive amplitude.

Cross-talks are undesired between the DC electrical signal injected to the laser section 670 and the high-frequency electrical signal applied to the EA modulator section. In order to prevent the cross-talks, in the second connection waveguide section 680, the second lower waveguide layer 83 and the second upper waveguide layer 85 may be formed of semi-insulating semiconductor layers. The second waveguide layer 84 may be also an intrinsic semiconductor that is not intentionally doped with impurities, and electrically may have a high resistance. The second lower waveguide layer 83 and the second upper waveguide layer 85 may be not always required to be a semi-insulating semiconductor. A high resistance may be achieved by doping the conductive semiconductor layer with impurities. For example, a high resistance may be achieved by adding protons to the p-type semiconductor layer. Further, a p-type semiconductor layer having a resistance higher than that of the n-type semiconductor layer may be used.

According to the sixth example implementation, the laser section 670 having a light emitting function and the EA modulator sections (610A and 610B) may be integrated on the same substrate, and hence a small-size, low-capacitance, and high-extinction-ratio EA modulator can be achieved. Differential drive may be performed in the EA modulators described in other example implementations and modification examples. Similarly, single-ended drive may be performed in the EA modulator of the sixth example implementation. In the case of the differential drive, it may be preferred that the absorption layers of the first EA modulator section 610A and the second EA modulator section 610B have the same dimension and the same semiconductor structure.

In the present invention, two EA modulator sections may be integrated on the substrate with the connection waveguide section interposed therebetween, and the two EA modulator sections may be electrically connected in series to each other via the planar connection medium. In a case in which one EA modulator section has a p-(absorption layer)-n structure from the upper side toward the substrate in the stacking direction of the semiconductor layer, the other EA modulator section may have an n-(absorption layer)-p multilayer structure from the upper side toward the substrate 3. When a negative bias is applied to the p-type semiconductor layer of the one EA modulator section, and the n-type semiconductor layer of the other EA modulator section is connected to the ground potential, the effects of the present invention can be obtained. At this time, the electrical connection between the n-type semiconductor layer of the one EA modulator section and the p-type semiconductor layer of the other EA modulator section is achieved via the connection medium.

The connection medium may have a planar structure. In this case, the planar structure means that the connection medium does not may have a three-dimensional structure that is connected to the upper surface of the mesa structure, from the region in which no mesa structure is arranged along the side surface of the mesa structure. Accordingly, even though the connection medium may be planar, it may not be that the connection medium has no thickness. The connection medium may be a semiconductor layer included in the connection waveguide section. Further, the connection medium may be a conductive semiconductor layer or a metal electrode which may be connected to both of the n-type semiconductor layer of one EA modulator section and the p-type semiconductor layer of the other EA modulator section. When the connection medium is the semiconductor layer included in the connection waveguide section, the semiconductor layer may be any one of the n-type semiconductor layer or the p-type semiconductor layer. It may be preferred that the semiconductor layer of the connection waveguide section arranged between the p-type semiconductor layer of the one EA modulator section and the n-type semiconductor layer of the other EA modulator section be a semi-insulating semiconductor layer or a semiconductor layer increased in resistance.

Further, when the differential drive is performed, a reverse phase signal being a negative bias may be applied to the p-type semiconductor layer of the one EA modulator section, and a positive phase signal being a positive bias may be applied to the n-type semiconductor layer of the other EA modulator section.

The EA modulator may further include a laser section and a second connection waveguide section. The second connection waveguide section may be arranged between the laser section and the one EA modulator section. In order to enhance electrical isolation between the electrical signal applied to the laser section and the electrical signal applied to the EA modulator section, the second connection waveguide section may be desired to be formed of a semi-insulating semiconductor layer or a semiconductor layer increased in resistance.

The EA modulator may be used as an optical semiconductor device mounted on the submount. The electrical signal from the outside may be transmitted to the EA modulator via a pad arranged on the submount.

While there have been described what are at present considered to be certain embodiments of the invention, it will be understood that various modifications may be made thereto, and it is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An electro-absorption modulator, comprising:
a semi-insulating semiconductor layer;
a first electro-absorption modulator section including a first n-type semiconductor layer, a first absorption layer, and a first p-type semiconductor layer which are grown in the stated order on the semi-insulating semiconductor layer;
a second electro-absorption modulator section including a second p-type semiconductor layer, a second absorption layer, and a second n-type semiconductor layer which are grown in the stated order on the semi-insulating semiconductor layer;
a connection waveguide layer arranged between the first absorption layer and the second absorption layer;
a first EA electrode electrically connected to the first p-type semiconductor layer and electrically connected to an outside;
a second EA electrode electrically connected to the second n-type semiconductor layer and electrically connected to the outside; and
a connection medium configured to electrically connect the first n-type semiconductor layer and the second p-type semiconductor layer to each other to connect the first electro-absorption modulator section and the second electro-absorption modulator section in series to each other.

2. The electro-absorption modulator according to claim 1, wherein the connection medium is arranged planarly.

3. The electro-absorption modulator according to claim 1, further comprising a connection waveguide section arranged between the first electro-absorption modulator section and the second electro-absorption modulator section, the connection waveguide section including the connection medium,
wherein the connection medium is a connection semiconductor layer arranged between the first n-type semiconductor layer of the first electro-absorption modulator section and the second p-type semiconductor layer of the second electro-absorption modulator section.

4. The electro-absorption modulator according to claim 3,
wherein the connection waveguide section includes the connection waveguide layer,
wherein the electro-absorption modulator further comprises a mesa structure, and
wherein the first n-type semiconductor layer, the second p-type semiconductor layer, and the connection waveguide layer each form a lower layer of the mesa structure.

5. The electro-absorption modulator according to claim 3,
wherein the connection waveguide section includes the connection waveguide layer,
wherein the electro-absorption modulator further comprises a mesa structure, and
wherein the first n-type semiconductor layer, the second p-type semiconductor layer, and the connection waveguide layer each form an upper layer of the mesa structure.

6. The electro-absorption modulator according to claim 1, further comprising a spacer layer between the semi-insulating semiconductor layer and each of the first n-type semiconductor layer and the second p-type semiconductor layer,
wherein the spacer layer is a conductive semiconductor layer electrically and physically connected to the first n-type semiconductor layer and the second p-type semiconductor layer, and
wherein the connection medium is the spacer layer.

7. The electro-absorption modulator according to claim 6, further comprising a connection waveguide section arranged between the first electro-absorption modulator section and the second electro-absorption modulator section, the connection waveguide section including an upper waveguide layer arranged between the first p-type semiconductor layer and the second n-type semiconductor layer,
wherein the upper waveguide layer is one of a semi-insulating semiconductor layer or a high-resistance semiconductor layer.

8. The electro-absorption modulator according to claim 6, further comprising a connection waveguide section arranged between the first electro-absorption modulator section and the second electro-absorption modulator section, the connection waveguide section including a lower waveguide layer arranged between the first n-type semiconductor layer and the second p-type semiconductor layer,
wherein the lower waveguide layer is one of a semi-insulating semiconductor layer or a high-resistance semiconductor layer.

9. The electro-absorption modulator according to claim 1, further comprising:
a mesa structure in which the first p-type semiconductor layer and the second n-type semiconductor layer each form an upper layer of the mesa structure; and
a spacer layer arranged on the mesa structure,
wherein the spacer layer is a conductive semiconductor layer electrically and physically connected to the first p-type semiconductor layer and the second n-type semiconductor layer, and
wherein the connection medium is the spacer layer.

10. The electro-absorption modulator according to claim 1, further comprising:
a mesa structure including the first absorption layer and the second absorption layer; and
a metal connection electrode electrically and physically connected to the first n-type semiconductor layer and the second p-type semiconductor layer,
wherein the metal connection electrode is a connection medium arranged apart from the mesa structure.

11. The electro-absorption modulator according to claim 1, further comprising:
a mesa structure in which the first p-type semiconductor layer and the second n-type semiconductor layer each form an upper layer of the mesa structure; and
a metal connection electrode provided on an upper surface of the mesa structure, the metal connection electrode being electrically and physically connected to the first p-type semiconductor layer and the second n-type semiconductor layer,
wherein the metal connection electrode is the connection medium, and is arranged only on the upper surface of the mesa structure.

12. The electro-absorption modulator according to claim 1,
wherein a negative-bias electrical signal is applied to the first EA electrode, and
wherein the second EA electrode is connected to a reference potential.

13. The electro-absorption modulator according to claim 1,
wherein a negative-bias electrical signal being a differential signal is applied to the first EA electrode, and
wherein a positive-bias electrical signal being the differential signal is applied to the second EA electrode.

14. The electro-absorption modulator according to claim 1, further comprising a mesa structure in which the first p-type semiconductor layer and the second n-type semiconductor layer each form an upper layer of the mesa structure,
wherein the first EA electrode is connected to the first p-type semiconductor layer on an upper surface of the mesa structure, and
wherein the second EA electrode is connected to the second n-type semiconductor layer on the upper surface of the mesa structure.

15. The electro-absorption modulator according to claim 1, further comprising a mesa structure in which the first p-type semiconductor layer and the second n-type semiconductor layer each form an upper layer of the mesa structure,
wherein the first EA electrode is connected to the first p-type semiconductor layer in a region separated from the mesa structure, and
wherein the second EA electrode is connected to the second n-type semiconductor layer in a region separated from the mesa structure.

16. The electro-absorption modulator according to claim 1, further comprising:
a mesa structure including the first absorption layer and the second absorption layer; and
a buried layer arranged on a side surface of the mesa structure in a direction perpendicular to a direction in which the mesa structure extends.

17. The electro-absorption modulator according to claim 1, further comprising:
a connection waveguide section arranged between the first electro-absorption modulator section and the second electro-absorption modulator section;
a laser section formed on the semi-insulating semiconductor layer; and
a second connection waveguide section arranged between the laser section and one of the first electro-absorption modulator section or the second electro-absorption modulator section.

18. The electro-absorption modulator according to claim 17,
wherein the laser section includes an n-type laser lower cladding layer, an active layer, and a p-type laser upper cladding layer which are grown in the stated order on the semi-insulating semiconductor layer, and
wherein the second connection waveguide section includes a lower waveguide layer being a semi-insulating semiconductor, a waveguide layer, and an upper waveguide layer being a semi-insulating semiconductor which are grown in the stated order on the semi-insulating semiconductor layer.

19. An optical semiconductor device, comprising:
the electro-absorption modulator of claim 1; and
a submount on which the electro-absorption modulator is mounted,
wherein the submount includes:
a first pad;
a second pad;
a third pad;
a fourth pad; and
a matching resistor,
wherein the first pad and the first EA electrode are electrically connected to each other,
wherein the second pad and the second EA electrode are electrically connected to each other,
wherein the third pad and the first EA electrode are electrically connected to each other,
wherein the matching resistor is arranged between the third pad and the fourth pad, and
wherein the fourth pad is connected to a ground potential.

20. The optical semiconductor device according to claim 19,
wherein a negative-bias electrical signal is applied to the first EA electrode via the first pad, and
wherein the second EA electrode is connected to a reference potential via the second pad.
